(19) United States
(12) Patent Application Publication
(10) Pub. No.: US 2025/0382492 A1
(43) Pub. Date: Dec. 18, 2025

(54) LAMINATE, METHOD FOR MANUFACTURING LAMINATE, HOLLOW STRUCTURE, AND ELECTRONIC COMPONENT

(71) Applicant: TORAY Industries, Inc., Tokyo (JP)

(72) Inventors: Yutaro KOYAMA, Otsu-shi (JP); Hitoshi ARAKI, Otsu-shi (JP)

(73) Assignee: TORAY Industries, Inc., Tokyo (JP)

(21) Appl. No.: 18/832,998

(22) PCT Filed: Jan. 30, 2023
(86) PCT No.: PCT/JP2023/002867

§ 371 Date: Jul. 25, 2024

(30) Foreign Application Priority Data
Feb. 2, 2022 (JP) 2022-014663

(51) Int. Cl. C09D 135/02; B32B 1/00; B32B 15/088; B32B 27/26; B32B 27/28; B32B 27/34

(52) U.S. Cl. CPC C09D 135/02; B32B 1/00; B32B 15/088; B32B 27/26; B32B 27/281; B32B 27/34; B32B 2250/03; B32B 2307/206; B32B 2307/7376

(57) ABSTRACT

Provided is a laminate that suffers little wiring corrosion during storage under high temperature and high humidity conditions. It is a laminate including a metal wire (M1) with a thickness of 0.1 to 5 μm, a relief pattern of an organic insulating film (P1) with a thickness of 0.5 to 4 μm, and a metal wire (M2) with a thickness of 0.1 to 5 μm which are disposed in this order on a piezoelectric substrate, wherein the organic insulating film (P1) includes a cured product obtainable by curing a photosensitive resin composition containing an alkali soluble resin (A) and a naphthoquinone diazide compound (E), the naphthoquinone diazide compound (E) accounting for 5 to 25 parts by mass relative to 100 parts by mass of the alkali soluble resin (A), and the ion elution quantity from the organic insulating film (P1) being 2,000 ppm or less as determined by an ion elution quantity measurement method.

### TECHNICAL FIELD

The present invention relates to a laminate, a method for manufacturing a laminate, a hollow structure, and an electronic component.

### BACKGROUND ART

For high speed, high quality communication by electronic devices, electronic components such as MEMS (micro electro mechanical systems) are essential technologies. As recent electronic devices become smaller, wiring designs of electronic components have become more intricate and complex.

To realize increased design freedom of wiring designs, devices using insulating materials such as polyimide at wiring intersections have been disclosed. (Patent Documents 1-4)

### PRIOR ART DOCUMENTS

### Patent Documents

Patent document 1: Japanese Unexamined Patent Publication (Kokai) No. 2004-282707
Patent document 2: Japanese Unexamined Patent Publication (Kokai) No. HEI 5-167387
Patent document 3: Japanese Unexamined Patent Publication (Kokai) No. HEI 7-30362
Patent document 4: International Publication WO 2011/050351

### SUMMARY OF INVENTION

### Problems to be Solved by the Invention

However, there have been problems with laminates using conventional insulating materials because they are highly corrosive to metal wiring under high temperature and high humidity conditions.

### Means of Solving the Problems

To solve the above problems, the present invention has the following configuration.

[1] A laminate including:
a metal wire (M1) with a thickness of 0.1 to 5 μm,
a relief pattern of an organic insulating film (P1) with a thickness of 0.5 to 4 μm, and
a metal wire (M2) with a thickness of 0.1 to 5 μm
which are disposed in this order on a piezoelectric substrate: wherein:
the organic insulating film (P1) includes a cured product obtainable by curing a photosensitive resin composition containing an alkali soluble resin (A) and a naphthoquinone diazide compound (E),
the naphthoquinone diazide compound (E) accounting for 5 to 25 parts by mass relative to 100 parts by mass of the alkali soluble resin (A), and
the ion elution quantity from the organic insulating film (P1) being 2,000 ppm or less as determined by the ion elution quantity measurement method described below:

### (Ion Elution Quantity Measurement Method)

the organic film is immersed in pure water with a mass ten times that of the film and then subjected to hot water extraction at 121° C. for 20 hours, followed by collecting the supernatant of the extract to provide a test liquid, and the test liquid and standard solutions of the target ions are introduced into an ion chromatograph, and the concentrations of the formate ion, acetate ion, propionate ion, and sulfate ion in the test liquid are measured by the working curve based measurement method and converted to the mass of the eluted ions relative to the mass of the organic film to determine the ion elution quantity.

[2] A laminate including:
a metal wire (M1) with a thickness of 0.1 to 5 μm,
a relief pattern of an organic insulating film (P1) with a thickness of 0.5 to 4 μm, and
a metal wire (M2) with a thickness of 0.1 to 5 μm
which are disposed in this order on a piezoelectric substrate, wherein:
the organic insulating film (P1) includes a cured product obtainable by curing a photosensitive resin composition containing an alkali soluble resin (A), an oxime based photopolymerization initiator (B), and a radical polymerizable compound (C),
the oxime based photopolymerization initiator (B) accounting for 1 to 20 parts by mass relative to 100 parts by mass of the alkali soluble resin (A),
the oxime based photopolymerization initiator (B) containing a compound as represented by the formula (1) and a compound as represented by the formula (2),
the ratio in mass between the compound represented by the formula (1) and the compound represented by the formula (2) being 1:1 to 20:1, and
the ion elution quantity from the organic insulating film (P1) being 2,000 ppm or less as determined by the ion elution quantity measurement method described below:

### (Ion Elution Quantity Measurement Method)

the organic film is immersed in pure water with a mass ten times that of the film and then subjected to hot water extraction at 121° C. for 20 hours, followed by collecting the supernatant of the extract to provide a test liquid, and the test liquid and standard solutions of the target ions are introduced into an ion chromatograph, and the concentrations of the formate ion, acetate ion, propionate ion, and sulfate ion in the test liquid are measured by the working curve based measurement method and converted to the mass of the eluted ions relative to the mass of the organic film to determine the ion elution quantity.

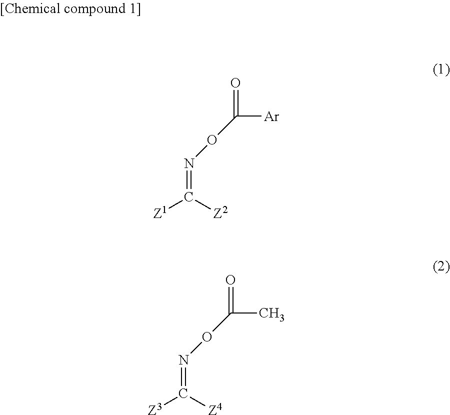

(In the formula (1), Ar is an aryl group having 6 to 20 carbon atoms; Z¹ is an organic group as represented by any of formulas (3) to (6); and Z² is a hydrogen atom or a monovalent organic group having 1 to 20 carbon atoms. In the formula (2), Z³ is an organic group as represented by any of the formulas (3) to (6), and Z⁴ is a hydrogen atom or a monovalent organic group having 1 to 20 carbon atoms.)

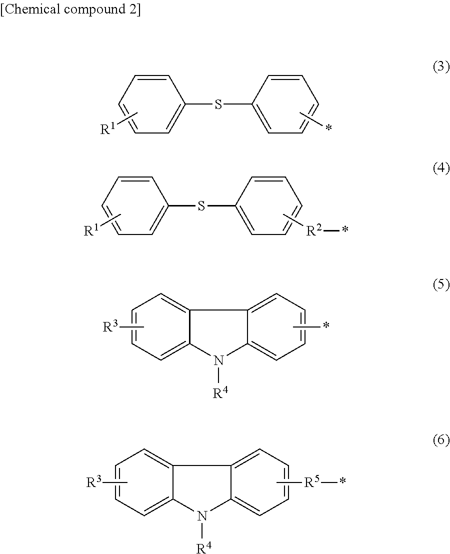

(In the formulas (3) to (6), R¹ and R³ each denote a hydrogen atom or a monovalent organic group having 1 to 20 carbon atoms; R² and R⁵ each denote a divalent organic group having 1 to 20 carbon atoms; and R⁴ denotes a monovalent organic group having 1 to 20 carbon atoms.)

[3] The laminate according to either [1] or [2], wherein the test liquid of the organic insulating film (P1) prepared above in the procedure for ion elution quantity measurement method has a conductivity of 500 μS/cm or less.

[4] The laminate according to any one of [1] to [3], wherein the plane where the piezoelectric substrate is in contact with the metal wire (M1) makes an angle of 20° to 60° with the plane where the relief pattern of the organic insulating film (P1) is in contact with the metal wire (M2).

[5] The laminate according to any one of [1] to [4], wherein the alkali soluble resin (A) includes at least one selected from the group consisting of polyimide, polybenzoxazole, polyamide, precursors thereof, and copolymers thereof.

[6] The laminate according to any one of [2] to [5], wherein the ratio in mass between the compound represented by the formula (1) and the compound represented by the formula (2) is 4:1 to 20:1.

[7] The laminate according to any one of [2] to [5], wherein the radical polymerizable compound (C) further includes a compound as represented by the formula (7) and a compound as represented by the formula (8), the ratio in mass between the compound represented by the formula (7) and the compound represented by the formula (8) being 1:9 to 5:5:

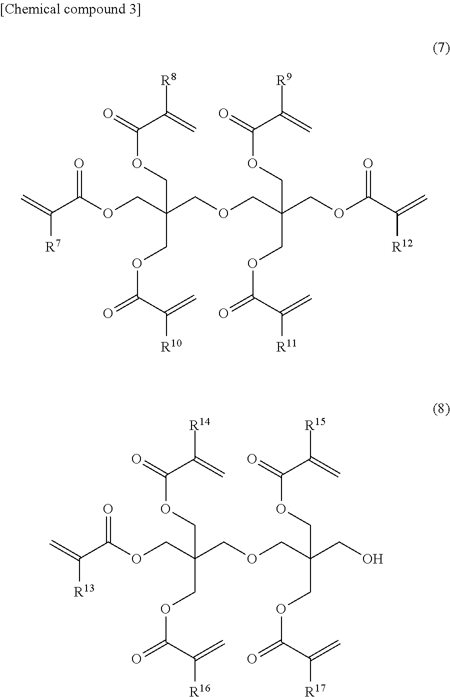

wherein in the formulas (7) and (8), R⁷ to R¹⁷ are each independently a hydrogen atom or a methyl group.

[8] The laminate according to any one of [1] to [7], wherein the photosensitive resin composition contains a thermally crosslinkable compound (D), the thermally crosslinkable compound (D) including a polyfunctional epoxy group-containing compound (D-1) and a polyfunctional alkoxymethyl group-containing compound (D-2), the polyfunctional epoxy group-containing compound (D-1) accounting for 5 to 30 parts by mass relative to 100 parts by mass of the alkali soluble resin (A), and the polyfunctional alkoxymethyl group-containing compound (D-2) accounting for 1 to 10 parts by mass relative thereto.

[9] A method for manufacturing a laminate including the following steps in that order:
a step (1) for forming a metal wire (M1) on a piezoelectric substrate,
a step (2) for applying a photosensitive resin composition over the piezoelectric substrate and the metal wire (M1) and drying it by heating at 80° C. to 130° C. to form a photosensitive resin film on the substrate,
a step (3) for exposing the photosensitive resin film to light through a mask to an exposure dose of 150 to 2,000 mJ/cm²,
a step (4) for heating the light-exposed photosensitive resin film at 80° C. to 130° C.,
a step (5) for removing the unexposed regions with an alkaline aqueous solution to develop the photosensitive resin film,
a step (6) for heat-treating the developed photosensitive resin film at 200° C. to 280 to form a relief pattern of an organic insulating film (P1), and
a step (7) for forming a metal wire (M2) on the piezoelectric substrate and the organic insulating film (P1).

[10] The method for manufacturing a laminate according to [9], wherein the thickness of the light-exposed region of the photosensitive resin film after developing for 80 seconds and that after developing for 140 seconds in the step (5) differ by 0.20 μm or less.

[11] The method for manufacturing a laminate according to either [9] or [10], further comprising a step (5-1) between the step (5) and the step (6) for heating the developed photosensitive resin film from a temperature of 100° C. or less to a temperature of 150° C. to 200° C. at a heating rate of 10° C./min or more.

[12] The method for manufacturing a laminate according to any one of [9] to [11], further comprising a step (5-2) between the step (5) and the step (6) for exposing the developed photosensitive resin film to light to an exposure dose of 1,000 to 3,000 mJ/cm².

[13] A hollow structure comprising the laminate according to any one of [1] to [12], a hollow structure support member (P2), and a hollow structure roof member (P3).

[14] The hollow structure according to [13], wherein the hollow structure support member (P2) and the hollow structure roof member (P3) are organic films containing at least one alkali soluble resin (A) selected from the group consisting of polyimide, polybenzoxazole, polyamide, precursors thereof, and copolymers thereof.

[15] The hollow structure according to either [13] or [14], wherein the total ion elution quantity of the organic insulating film (P1) with a thickness of 0.5 to 4 μm, the hollow structure support member (P2), and the hollow structure roof member (P3) is 2,000 ppm or less, wherein the organic insulating film (P1) with a thickness of 0.5 to 4 μm, the hollow structure support member (P2), and the hollow structure roof member (P3) are examined separately by the ion elution quantity measurement method.

[16] An electronic component comprising the hollow structure according to any one of [13] to [15].

### Advantageous Effects of the Invention

The present invention serves to suppress corrosion of metal wires during storage under high temperature and high humidity conditions.

### BRIEF DESCRIPTION OF THE DRAWINGS

FIG. 1 This is a diagram showing a laminate according to the present invention.

FIG. 2 This is a diagram showing a cross section of a laminate according to the present invention.

FIG. 3 This is a diagram showing a cross section of a hollow structure that contains a laminate according to the present invention.

### DESCRIPTION OF PREFERRED EMBODIMENTS

The present invention provides a laminate comprising:
a metal wire (M1) with a thickness of 0.1 to 5 μm,
a relief pattern of an organic insulating film (P1) with a thickness of 0.5 to 4 μm, and
a metal wire (M2) with a thickness of 0.1 to 5 μm
which are disposed in this order on a piezoelectric substrate,
wherein the organic insulating film (P1) includes a cured product obtainable by curing a photosensitive resin composition containing an alkali soluble resin (A) and a naphthoquinone diazide compound (E),
the naphthoquinone diazide compound (E) accounting for 5 to 25 parts by mass relative to 100 parts by mass of the alkali soluble resin (A), and
the ion elution quantity of the organic insulating film (P1) measured by the ion elution quantity measurement method described below being 2,000 ppm or less.

### (Ion Elution Quantity Measurement Method)

The organic film is immersed in pure water with a mass ten times that of the film and then subjected to hot water extraction at 121° C. for 20 hours, followed by collecting the supernatant of the extract to provide a test liquid. The test liquid and standard solutions of the target ions are introduced into an ion chromatograph, and the concentrations of the formate ion, acetate ion, propionate ion, and sulfate ion in the test liquid are measured by the working curve based measurement method and converted to the mass of each eluted ion relative to the mass of the organic film to determine the ion elution quantity.

In cases related to measurement of the laminate according to the present invention by the ion elution quantity measurement method, the organic film refers to the organic insulating film (P1).

If the total elution quantity of the formate ion, acetate ion, propionate ion, and sulfate ion from the organic insulating film (P1) is 2,000 ppm or less as determined by the aforementioned ion elution quantity measurement method, it is preferable because it serves to suppress the corrosion of the metal wires in the laminate under high temperature and high humidity conditions, and it is more preferably 1,000 ppm or less from the viewpoint of corrosion suppression and still more preferably 500 to 0 ppm. The lower limit of measurement of the ion chromatograph used for the ion elution quantity measurement method should be 0 ppm.

Acid ions eluted from an organic insulating film under high temperature and high humidity conditions can accelerate ionization of metal wires and are considered to act as a cause of corrosion. Electronic components containing piezoelectric substrates and metal wires are greatly affected by changes in characteristics caused by metal corrosion, and therefore, it is necessary to further reduce the acid ion elution quantity from organic insulating films compared to conventional films.

The elution quantity of the formate ion, acetate ion, propionate ion, and sulfate ion should each preferably be 2,000 ppm or less, more preferably 1,000 ppm or less, and still more preferably 500 to 0 ppm.

More specifically, the ion elution quantity measurement method is carried out as described below.

The organic film to be examined for ion elution quantity is separated in a predetermined amount from the laminate. When measuring the ion elution quantity from the resin composition used to form the organic film, a cured product prepared by heat-treating the resin composition in a liquid or sheet-like form may be used. A cured product can be prepared, for example, by a procedure in which a silicon substrate is coated or laminated with a resin composition and then it is heat-treated in an oven and immersed in a hydrofluoric acid solution, followed by peeling it off, or by a procedure in which a resin sheet is formed on polyethylene terephthalate (PET) and transferred using a rubber roller onto a polytetrafluoroethylene (PTFE) film heated on a hot plate, followed by heat-treating it and peeling it off from the PTFE film. The resulting cured product and pure water with a mass ten times that of the film are put in a pressure sealed container made of PTFE and then subjected to hot water extraction at 121° C. for 20 hours, followed filtering the supernatant of the extract through a membrane filter to provide a test liquid. The cured product preferably has a mass of 0.1 to 5.0 g, more preferably 0.3 to 3.0 g to ensure high workability and stability during ion extraction. The cured film may be freeze-crushed using liquid nitrogen if necessary. The pure water used here should be distilled and ion-exchanged to suit reagent preparation and trace analysis tests as specified in JIS K 0557 (1998). The procedure for the hot water pressure extraction method was set up with reference to Hashimoto, Yoshimi “Bunseki Kagaku (Analytical Chemistry), 49, 8 (2000), and the temperature conditions for extraction were set up with reference to Kitamura, Ai. “Network Polymer”, 33, 3 (2012).

The test liquid is analyzed in accordance with the Japanese Industrial Standard JIS K 0127 (2013) “Ion Chromatography General Rules, Ion Chromatography Method”. A standard solution of the formate ion, acetate ion, propionate ion, or sulfate ion is introduced separately into an ion chromatograph and a working curve is prepared. Then, the peak area measured for a 25 μL of the test liquid is used with the working curve to determine the concentrations of the formate ion, acetate ion, propionate ion, and sulfate ion separately. It is converted to the mass of each eluted ion relative to the mass of the organic film to provide the ion elution quantity.

The piezoelectric substrates that are suitable for the present invention include those made of lithium tantalate, lithium niobate, or gallium arsenide, or substrates formed by coating their surfaces with passivation films of silicon nitride or silicon oxide, though the invention is not limited thereto.

A metal wire (M1) is formed on a piezoelectric substrate. It is preferable for the metal wire (M1) to be disposed directly on the piezoelectric substrate because this serves to obtain a high piezoelectric effect. The metal wire (M1) can be made of materials such as aluminum and copper, but it is not limited thereto. There are some methods for forming the metal wire (M1). They include a process in which a metal sputtered film is formed and openings of a patterned resist are etched, and a process in which an electroplated wire is formed in openings of a resist. Other generally known methods may also be used. When its thickness is 0.1 to 5 μm, it serves to achieve electrical connection and allows the overall height of the laminate to be low.

A relief pattern of an organic insulating film (P1) is formed so as to cover the metal wire (M1) disposed on the piezoelectric substrate. A passivation film of silicon nitride, silicon oxide, etc., may be formed on the metal wire (M1) and the organic insulating film (P1) in such a manner that the combined thickness with that of the metal wire (M1) is in the range of 0.1 to 5 μm, but it is preferable for the metal wire (M1) and the organic insulating film (P1) to be in contact with each other because it serves to achieve a high piezoelectric effect. The relief pattern of the organic insulating film (P1) is produced by patterning and curing a photosensitive resin composition into a desired shape. When having a thickness of 0.5 μm or more, the organic insulating film (P1) can maintain high insulation efficiency, heat resistance, and reliability, whereas when it is 4 μm or less, the metal wire (M2) formed on the organic insulating film (P1) can be prevented from disconnection and the overall height of the laminate can be decreased.

The metal wire (M2) is formed on the metal wire (M1) and organic insulating film (P1) disposed on the piezoelectric substrate. The metal wire (M2) is disposed on the same piezoelectric substrate as the metal wire (M1), but it is insulated by the organic insulating film (P1) from the metal wire (M1) in the area where it intersects the metal wire (M1). As in the case of the metal wire (M1), the metal wire (M2) is formed of aluminum, copper, or the like by means of a process in which a sputtered film is formed first and a plated wire is produced in the openings in the patterned resist. Other generally known methods may also be used. When its thickness is 0.1 to 5 μm, it serves to achieve electrical connection and allows the overall height of the laminate to be low.

The test liquid of the organic insulating film (P1) prepared in the procedure of the ion elution quantity measurement method preferably has a conductivity of 500 μS/cm or less. If the conductivity of the test liquid is 500 μS/cm or less, it serves to reduce the diffusion of acid ions under high temperature and high humidity conditions, thereby suppressing the corrosion of the metal wires in the laminate. From the viewpoint of corrosion suppression, it is more preferable for the test liquid to have a conductivity of 300 to 10 μS/cm. The conductivity of a test liquid can be measured using an ion chromatograph as mentioned above in the description of the ion elution quantity measurement method.

It is preferable that the plane where the piezoelectric substrate is in contact with the metal wire (M1) make an angle of 20° to 60° with the plane where the relief pattern of the organic insulating film (P1) is in contact with the metal wire (M2). The angle formed between the plane where the piezoelectric substrate is in contact with the metal wire (M1) and the plane where the relief pattern of the organic insulating film (P1) is in contact with the metal wire (M2) is the taper angle of the relief pattern of the organic insulating film (P1) on the piezoelectric substrate, and it is denoted by c in FIG. 2. When this is 20° or more, the organic insulating film (P1) can have a sufficient thickness to work as an insulation film, whereas when it is 60° or less, it serves to prevent the disconnection of the metal wire (M2) to be formed on the organic insulating film (P1).

The organic insulating film (P1) contains a cured product obtainable by curing a photosensitive resin composition that includes an alkali soluble resin (A) and a naphthoquinone diazide compound (E), wherein the naphthoquinone diazide compound (E) accounts for 5 to 25 parts by mass, more preferably 7 to 20 parts by mass, relative to 100 parts by mass of the alkali soluble resin (A).

The naphthoquinone diazide compound (E) tends to contain ions such as sulfate ions and can cause corrosion of the wires. If the content of the naphthoquinone diazide compound (E) is within the above range, it serves to suppress the corrosion of the wires.

For the present invention, being soluble in alkali means having a dissolution speed of 50 nm/min or more in the alkaline aqueous solution used as the developer. More specifically, a solution prepared by dissolving a resin specimen in γ-butyrolactone is spread over a silicon wafer and prebaked on a hot plate at 120° C. for 4 minutes to prepare a prebaked film with a film thickness of 10 μm±0.5 μm, and then the prebaked film is immersed for 1 minute in an alkaline aqueous solution selected from the group consisting of a 2.38 mass % aqueous solution of tetramethylammonium hydroxide, a 1 mass % aqueous solution of potassium hydroxide, and a 1 mass % aqueous solution of sodium hydroxide, all having a temperature of 2310° C., followed by rinsing with pure water. The dissolution speed determined from the measured loss of film thickness should be 50 nm/min or more.

It is preferable for the alkali soluble resin (A) to include at least one resin selected from the group consisting of polyimide, polybenzoxazole, polyamide, precursors of any thereof, epoxy resin, acrylic resin, polyhydroxystyrene, and copolymers thereof, of which the inclusion of polyimide, polybenzoxazole, or polyamide is more preferable. If these resins are contained, it serves to produce a cured product that is high in insulation efficiency, heat resistance, and reliability against high temperature storage and thermal shock.

The alkali soluble resin (A) preferably has at least one repeating unit selected from the repeating units shown below.

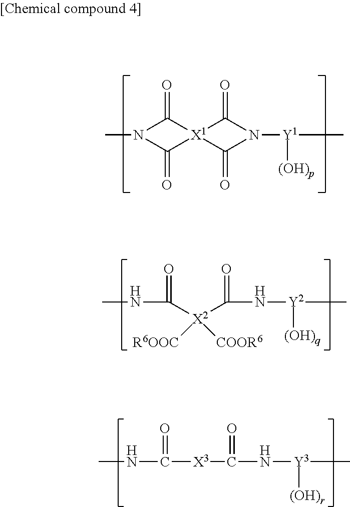

In the repeating units, X¹ and X² each represent an acid dianhydride residue; X³ represents a dicarboxylic acid residue; and Y¹(OH)ₚ, Y²(OH)_{q}, and Y³(OH)ᵣ each represent a diamine residue. Here, p, q, and r each represent an integer in the range of 0 to 4, and R⁶ represents a hydrogen atom or a monovalent organic group having 1 to 10 carbon atoms. Having at least one repeating unit selected from the repeating units shown above serves to form a laminate with high heat resistance.

Generally known materials may be used as the acid dianhydride and diamine mentioned above.

The alkali soluble resin (A) may have backbone chain ends capped with generally known monoamines, acid anhydrides, monocarboxylic acids, monoacid chlorides, or monoactive ester compounds.

When the polystyrene based weight average molecular weight (Mw) of the alkali soluble resin (A) is measured by gel permeation chromatography (GPC) using as developing solvent 99.3 mass % N-methyl-2-pyrrolidone, 0.2 mass % lithium chloride, and 0.5 mass % phosphoric acid, Mw is preferably 3,000 or more because this serves for easy production of a cured product by heat treatment. To produce a cured product with a high elongation degree and high heat resistance, it is more preferably 10,000 or more, more preferably 20,000 or more. On the other hand, if it is 200,000 or less, it is preferable because it serves to prepare a photosensitive resin that can be processed easily, and it is more preferably 100,000 or less, and still more preferably 70,000 or less to achieve high pattern processibility.

The present invention also provides a laminate including:
a metal wire (M1) with a thickness of 0.1 to 5 μm,
a relief pattern of an organic insulating film (P1) with a thickness of 0.5 to 4 μm, and
a metal wire (M2) with a thickness of 0.1 to 5 μm
which are disposed in this order on a piezoelectric substrate,
wherein the organic insulating film (P1) includes a cured product obtainable by curing a photosensitive resin composition containing an alkali soluble resin (A), an oxime based photopolymerization initiator (B), and a radical polymerizable compound (C),
the oxime based photopolymerization initiator (B) accounting for 1 to 20 parts by mass relative to 100 parts by mass of the alkali soluble resin (A),
the oxime based photopolymerization initiator (B) containing a compound as represented by the formula (1) and a compound as represented by the formula (2),
the ratio in mass between the compound represented by the formula (1) and the compound represented by the formula (2) being 1:1 to 20:1, and
the quantity of ion elution from the organic insulating film (P1) measured by the ion elution quantity measurement method described below being 2,000 ppm or less.

### (Ion Elution Quantity Measurement Method)

The organic film is immersed in pure water with a mass ten times that of the film and then subjected to hot water extraction at 121° C. for 20 hours, followed by collecting the supernatant of the extract to provide a test liquid. The test liquid and standard solutions of the target ions are introduced into an ion chromatograph, and the concentrations of the formate ion, acetate ion, propionate ion, and sulfate ion in the test liquid are measured by the working curve method and converted to the mass of eluted ions relative to the mass of the organic film to determine the ion elution quantity:

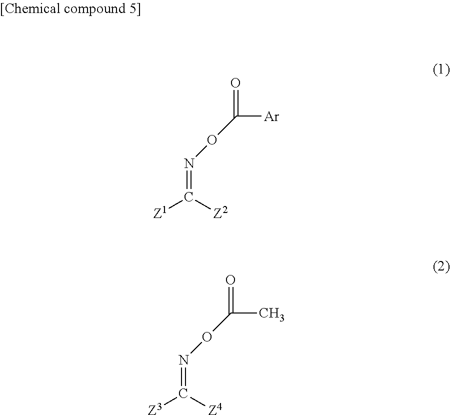

(In formula (1), Ar is an aryl group having 6 to 20 carbon atoms; Z¹ is an organic group as represented by any of formulas (3) to (6); and Z² is a hydrogen atom or a monovalent organic group having 1 to 20 carbon atoms. In the formula (2), Z³ is an organic group as represented by any of the formulas (3) to (6), and Z⁴ is a hydrogen atom or a monovalent organic group having 1 to 20 carbon atoms.)

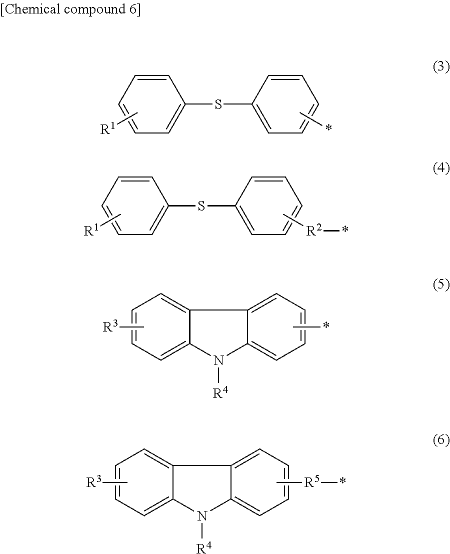

(In the formulas (3) to (6), R¹ and R³ each denote a hydrogen atom or a monovalent organic group having 1 to 20 carbon atoms; R² and R⁵ each denote a divalent organic group having 1 to 20 carbon atoms; and R⁴ denotes a monovalent organic group having 1 to 20 carbon atoms.) If the total elution quantity of the formate ion, acetate ion, propionate ion, and sulfate ion is 2,000 ppm or less when the organic insulating film (P1) is examined by the aforementioned ion elution quantity measurement method, it is preferable because it serves to suppress the corrosion of the metal wires in the laminate under high temperature and high humidity conditions, and it is more preferably 1,000 ppm or less from the viewpoint of corrosion suppression and still more preferably 500 to 0 ppm. The lower limit of measurement of the ion chromatograph used for the ion elution quantity measurement method should be 0 ppm.

Acid ions eluted from an organic insulating film under high temperature and high humidity conditions can accelerate the ionization of metal wires and are considered to act as a cause of corrosion. Electronic components containing piezoelectric substrates and metal wires are greatly affected by changes in characteristics caused by metal corrosion, and therefore, it is necessary to further reduce the acid ion elution quantity from the organic insulating films compared to conventional films.

The elution quantity of the formate ion, acetate ion, propionate ion, and sulfate ion should each preferably be 2,000 ppm or less, more preferably 1,000 ppm or less, and still more preferably 500 to 0 ppm.

More specifically, the ion elution quantity measurement method is carried out as described below.

The organic film to be examined for ion elution quantity is separated in a predetermined amount from the laminate. When measuring the ion elution quantity from the resin composition used to form the organic film, a cured product prepared by heat-treating the resin composition in a liquid or sheet-like form may be used. A cured product can be prepared, for example, by a procedure in which a silicon substrate is coated or laminated with a resin composition and then it is heat-treated in an oven and immersed in a hydrofluoric acid solution, followed by peeling it off, or a procedure in which a resin sheet is formed on polyethylene terephthalate (PET) and transferred using a rubber roller onto a polytetrafluoroethylene (PTFE) film heated on a hot plate, followed by heat-treating it and peeling it off from the PTFE film. The resulting cured product and pure water with a mass ten times that of the film are put in a pressure sealed container made of PTFE and then subjected to hot water extraction at 121° C. for 20 hours, followed filtering the supernatant of the extract through a membrane filter to provide a test liquid. The cured product preferably has a mass of 0.1 to 5.0 g, more preferably 0.3 to 3.0 g to ensure high workability and stability during ion extraction. The cured film may be freeze-crushed using liquid nitrogen if necessary. The pure water used here should be distilled and ion-exchanged to suit reagent preparation and trace analysis tests as specified in JIS K 0557 (1998). The procedure for the hot water pressure extraction method was set up with reference to Hashimoto, Yoshimi “Bunseki Kagaku (Analytical Chemistry), 49, 8 (2000), and the temperature conditions for extraction were set up with reference to Kitamura, Ai. “Network Polymer”, 33, 3 (2012).

The test liquid is analyzed in accordance with the Japanese Industrial Standard JIS K 0127 (2013) “Ion Chromatography General Rules, Ion Chromatography Method”. A standard solution of the formate ion, acetate ion, propionate ion, or sulfate ion is introduced separately into an ion chromatograph and a working curve is prepared. Then, the peak area measured for a 25 μL of the test liquid is used with the working curve to determine the concentrations of the formate ion, acetate ion, propionate ion, and sulfate ion separately. It is converted to the mass of each eluted ion relative to the mass of the organic film to provide the ion elution quantity.

The piezoelectric substrates that are suitable for the present invention include those of lithium tantalate, lithium niobate, or gallium arsenide, or substrates formed by coating their surfaces with passivation films of silicon nitride or silicon oxide, though the invention is not limited thereto.

A metal wire (M1) is formed on the piezoelectric substrate. It is preferable for the metal wire (M1) to be disposed directly on the piezoelectric substrate because this serves to obtain a high piezoelectric effect. The metal wire (M1) can be made of materials such as aluminum and copper, but it is not limited thereto. There are some methods for forming the metal wire (M1). They include a process in which a metal sputtered film is formed and openings of a patterned resist are etched, and a process in which an electroplated wire is formed in openings of a resist. Other generally known methods may also be used. When its thickness is 0.1 to 5 μm, it serves to achieve electrical connection and allows the overall height of the laminate to be low.

A relief pattern of an organic insulating film (P1) is formed so as to cover the metal wire (M1) disposed on the piezoelectric substrate. A passivation film of silicon nitride, silicon oxide, etc., may be formed on the metal wire (M1) and the organic insulating film (P1) in such a manner that the combined thickness with that of the metal wire (M1) is in the range of 0.1 to 5 μm, but it is preferable for the metal wire (M1) and the organic insulating film (P1) to be in contact with each other because it serves to achieve a high piezoelectric effect. The relief pattern of the organic insulating film (P1) is produced by patterning and curing a photosensitive resin composition into a desired shape. When having a thickness of 0.5 μm or more, the organic insulating film (P1) can maintain high insulation efficiency, heat resistance, and reliability, whereas when it is 4 μm or less, the metal wire (M2) formed on the organic insulating film (P1) can be prevented from disconnection and the overall height of the laminate can be decreased.

The metal wire (M2) is formed on the metal wire (M1) and organic insulating film (P1) disposed on the piezoelectric substrate. The metal wire (M2) is disposed on the same piezoelectric substrate as the metal wire (M1), but it is insulated by the organic insulating film (P1) from the metal wire (M1) in the area where it intersects the metal wire (M1). As in the case of the metal wire (M1), the metal wire (M2) is formed of aluminum, copper, or the like by means of a process in which a sputtered film is formed first and a plated wire is produced in the openings in the patterned resist. Other generally known methods may also be used. When its thickness is 0.1 to 5 μm, it serves to achieve electrical connection and allow the overall height of the laminate to be low.

The test liquid of the organic insulating film (P1) prepared in the procedure of the ion elution quantity measurement method preferably has a conductivity of 500 μS/cm or less. If the conductivity of the test liquid is 500 μS/cm or less, it serves to reduce the diffusion of acid ions under high temperature and high humidity conditions, thereby suppressing the corrosion of the metal wires in the laminate. From the viewpoint of corrosion suppression, it is more preferable for the test liquid to have a conductivity of 300 to 10 μS/cm. The conductivity of a test liquid can be measured using an ion chromatograph as mentioned above in the description of the ion elution quantity measurement method.

It is preferable that the plane where the piezoelectric substrate is in contact with the metal wire (M1) make an angle of 20° to 60° with the plane where the relief pattern of the organic insulating film (P1) is in contact with the metal wire (M2). The angle formed between the plane where the piezoelectric substrate is in contact with the metal wire (M1) and the plane where the relief pattern of the organic insulating film (P1) is in contact with the metal wire (M2) is the taper angle of the relief pattern of the organic insulating film (P1) on the piezoelectric substrate, and it is denoted by c in FIG. 2. When this is 20° or more, the organic insulating film (P1) can have a sufficient thickness to work as an insulation film, whereas when it is 60° or less, it serves to prevent the disconnection of the metal wire (M2) to be formed on the organic insulating film (P1). The organic insulating film (P1) contains a cured product produced by curing a photosensitive resin composition that includes an alkali soluble resin (A), an oxime based photopolymerization initiator (B), and a radical polymerizable compound (C).

The inclusion of an oxime based photopolymerization initiator (B) in the photosensitive resin composition serves to provide a resin composition that has high sensitivity and high resolution even when it is in the form of a thin film with a thickness of 0.5 to 4 μm, and this makes it possible to produce a fine relief pattern of the organic insulating film (P1).

The compound represented by the formula (1) does not generate low molecular weight acid ions in significant amounts when it is decomposed, and it can form a cured product that does not cause significant metal wire corrosion. The compound represented by the formula (2) generates acetate ions in significant amounts, but it remains highly sensitive even when it is in the form of a thin film with a thickness of 0.5 to 4 μm, and it can allow the resin composition to be photo-cured even when added in small amounts. When the ratio in mass between the compound represented by the formula (1) and the compound represented by the formula (2) is in the range specified above, a resin composition with high sensitivity and high resolution can be obtained even with small contents of acid ions, and this serves to produce a laminate that has a fine relief pattern of the organic insulating film (P1) while suffering little metal wire corrosion.

The above effect is realized when the oxime based photopolymerization initiator (B) accounts for 1 to 20 parts by mass relative to 100 parts by mass of the alkali soluble resin (A) with the ratio in mass between the compound represented by the formula (1) and the compound represented by the formula (2) being 1:1 to 20:1. The ratio in mass between the compound represented by the formula (1) and the compound represented by the formula (2) is more preferably 4:1 to 20:1.

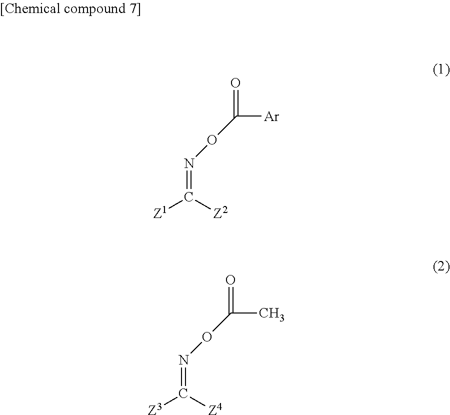

(In the formula (1), Ar is an aryl group having 6 to 20 carbon atoms; Z¹ is an organic group as represented by any of the formulas (3) to (6); and Z² is a hydrogen atom or a monovalent organic group having 1 to 20 carbon atoms. In the formula (2), Z³ is an organic group as represented by any of the formulas (3) to (6), and Z⁴ is a hydrogen atom or a monovalent organic group having 1 to 20 carbon atoms.

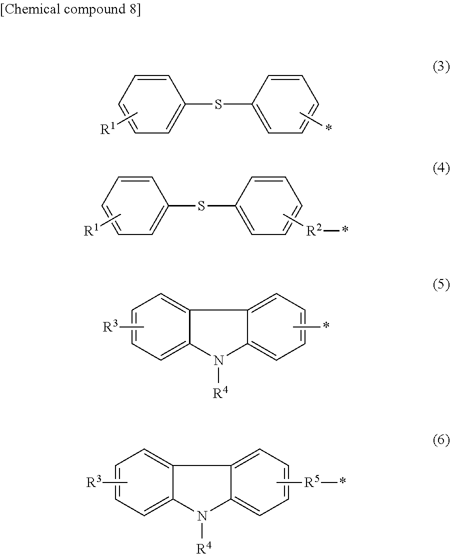

(In the formulas (3) to (6), R¹ and R³ each denote a hydrogen atom or a monovalent organic group having 1 to 20 carbon atoms; R² and R⁵ each denote a divalent organic group having 1 to 20 carbon atoms; and R⁴ denotes a monovalent organic group having 1 to 20 carbon atoms.

Examples of the compound represented by the formula (1) include 1,2-octanedione-1-[4-(phenylthio)phenyl]-2-(o-benzoyloxime), 1,2-propanedione-1-[4-(phenylthio)phenyl]-2-(o-benzoyloxime)-3-cyclopentane, IRGACURE (registered trademark) OXE-01 (trade name, manufactured by Ciba Specialty Chemicals Inc.), and PBG-305 (trade name, manufactured by Changzhou Tronly New Electronic Materials Co., Ltd.).

Examples of the compound represented by the formula (2) include 1-phenyl-1,2-butanedione-2-(o-methoxycarbonyl)oxime, 1-phenyl-1,2-propanedione-2-(o-methoxycarbonyl)oxime, 1-phenyl-1,2-propanedione-2-(o-ethoxycarbonyl)oxime, bis(α-isonitrosopropiophenone oxime)isophthal, IRGACURE (registered trademark) OXE-02 (trade name, manufactured by Ciba Specialty Chemicals Inc.), Adeka ARKLS NCI-831 and NCI-930 (trade names, manufactured by ADEKA Corporation).

In addition, other good photopolymerization initiators include the following photopolymerization initiators, which can be used as long as they do not generate acid ions in large amounts to cause significant wire corrosion.

Examples of such other photopolymerization initiators include benzophenones such as benzophenone, Michler's ketone, and 4,4-bis(diethylamino)benzophenone; benzylidenes such as 3,5-bis(diethylaminobenzylidene)-N-methyl-4-piperidone; coumarins such as 7-diethylamino-3-tenoylcoumarin; anthraquinones such as 2-t-butylanthraquinone; benzoins such as benzoinmethyl ether; mercapto based ones such as ethylene glycol di(3-mercaptopropionate); glycines such as N-phenylglycine; and α-aminoalkylphenones such as 2-benzyl-2-dimethylamino-1-(4-morpholinophenyl)-butane-1,2-methyl-1[4-methylthio]phenyl]-2-morpholinopropane-1-one.

The oxime based photopolymerization initiator (B) preferably accounts for 0.1 to 40 parts by mass relative to the total quantity, which accounts for 100 parts by mass (B), of the alkali soluble resin (A). If its content is 0.1 part by mass or more, it is preferable because it serves to generate a sufficient amount of radicals under light exposure and realize an improved sensitivity, whereas if it is 40 parts by mass or less, it serves to ensure a high processibility and realize the formation of a laminate with a total acid ion elution quantity of 2,000 ppm or less. To realize a high sensitivity while suppressing the acid ion content, it is preferable for the content of the oxime based photopolymerization initiator (B) to be 5 to 20 parts by mass relative to the total amount, which accounts for 100 parts by mass, of the alkali soluble resin (A).

For the present invention, being soluble in alkali means having a dissolution speed of 50 nm/min or more in the alkaline aqueous solution used as the developer. More specifically, a solution prepared by dissolving a resin specimen in γ-butyrolactone is spread over a silicon wafer and prebaked on a hot plate at 120° C. for 4 minutes to prepare a prebaked film with a film thickness of 10 μm±0.5 μm, and then the prebaked film is immersed for 1 minute in an alkaline aqueous solution selected from the group consisting of a 2.38 mass % aqueous solution of tetramethylammonium hydroxide, a 1 mass % aqueous solution of potassium hydroxide, and a 1 mass % aqueous solution of sodium hydroxide, all having a temperature of 23±10° C., followed by rinsing with pure water. The dissolution speed determined from the measured decrease in film thickness should be 50 nm/min or more.

It is preferable for the alkali soluble resin (A) to include at least one resin selected from the group consisting of polyimide, polybenzoxazole, polyamide, precursors of any thereof, epoxy resin, acrylic resin, polyhydroxystyrene, and copolymers thereof, of which the inclusion of polyimide, polybenzoxazole, or polyamide is more preferable. If these resins are contained, it serves to produce a cured product that is high in insulation efficiency, heat resistance, and reliability against high temperature storage and thermal shock.

The alkali soluble resin (A) preferably has at least one repeating unit selected from the repeating units shown below.

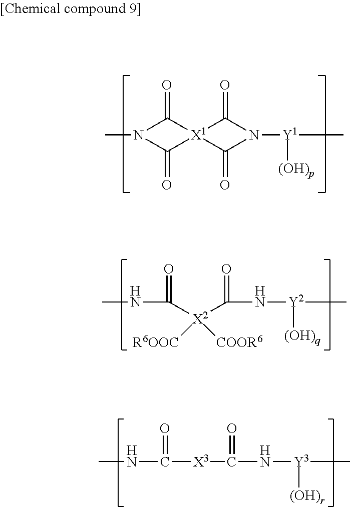

In the repeating units, X¹ and X² each represent an acid dianhydride residue; X³ represents a dicarboxylic acid residue; and Y¹(OH)ₚ, Y²(OH)_{q}, and Y³(OH)ᵣ each represent a diamine residue. Here, p, q, and r each represent an integer in the range of 0 to 4, and R⁶ represents a hydrogen atom or a monovalent organic group having 1 to 10 carbon atoms. Having at least one repeating unit selected from the repeating units shown above serves to form a laminate with high heat resistance.

Generally known materials may be used as the acid dianhydride and diamine mentioned above.

The alkali soluble resin (A) may have backbone chain ends capped with generally known monoamines, acid anhydrides, monocarboxylic acids, monoacid chlorides, or monoactive ester compounds.

When the polystyrene based weight average molecular weight (Mw) of the alkali soluble resin (A) is measured by gel permeation chromatography (GPC) using as developing solvent 99.3 mass % N-methyl-2-pyrrolidone, 0.2 mass % lithium chloride, and 0.5 mass % phosphoric acid, Mw is preferably 3,000 or more because this serves for easy production of a cured product by heat treatment. To produce a cured product with a high elongation degree and high heat resistance, it is more preferably 10,000 or more, more preferably 20,000 or more. On the other hand, if it is 200,000 or less, it is preferable because it serves to prepare a photosensitive resin that can be processed easily, and it is more preferably 100,000 or less, and still more preferably 70,000 or less to achieve high pattern processibility.

The term “radical polymerizable compound (C)” refers to a compound having one or more radical polymerizable functional groups in the molecule. Specific examples of the radical polymerizable compound (C) include ethylene glycol diacrylate, ethylene glycol dimethacrylate, diethylene glycol diacrylate, diethylene glycol dimethacrylate, triethylene glycol diacrylate, triethylene glycol dimethacrylate, tetraethylene glycol diacrylate, tetraethylene glycol dimethacrylate, trimethylolpropane diacrylate, trimethylolpropane triacrylate, trimethylolpropane dimethacrylate, trimethylolpropane trimethacrylate, 1,3-butanediol diacrylate, 1,3-butanediol dimethacrylate, neopentyl glycol diacrylate, 1,4-butanediol diacrylate, 1,4-butanediol dimethacrylate, 1,6-hexanediol diacrylate, 1,6-hexanediol dimethacrylate, 1,9-nonanediol dimethacrylate, 1,10-decanediol dimethacrylate, dimethylol tricyclodecane diacrylate, pentaerythritol triacrylate, pentaerythritol trimethacrylate, pentaerythritol tetraacrylate, pentaerythritol tetramethacrylate, dipentaerythritol hexaacrylate, dipentaerythritol hexamethacrylate, dipentaerythritol pentaacrylate, dipentaerythritol pentamethacrylate, 1,3-diacryloyloxy-2-hydroxypropane, 1,3-dimethacryloyloxy-2-hydroxypropane, N,N′-methylene bisacrylamide, BP-6EM, DCP-A (trade names, manufactured by Kyoeisha Chemical Co., Ltd.), AH-600 (trade name, manufactured by Kyoeisha Chemical Co., Ltd.), AT-600 (trade name, Kyoeisha Chemical Co., Ltd.), UA-306H (trade name, manufactured by Kyoeisha Chemical Co., Ltd.), UA-306T (trade name, manufactured by Kyoeisha Chemical Co., Ltd.), ethylene oxide-modified bisphenol A diacrylate, ethylene oxide-modified bisphenol A dimethacrylate, isocyanurate ethylene oxide-modified diacrylate, Aronix (registered trademark) M-315 (trade name, manufactured by Toagosei Co., Ltd.), and other isocyanurate ethylene oxide-modified triacrylate products. In particular, the radical polymerizable compound (C) preferably contains a compound as represented by the formula (7) and a compound as represented by the formula (8), and the ratio in mass between the compound represented by formula (7) and the compound represented by the formula (8) is preferably 1:9 to 5:5.

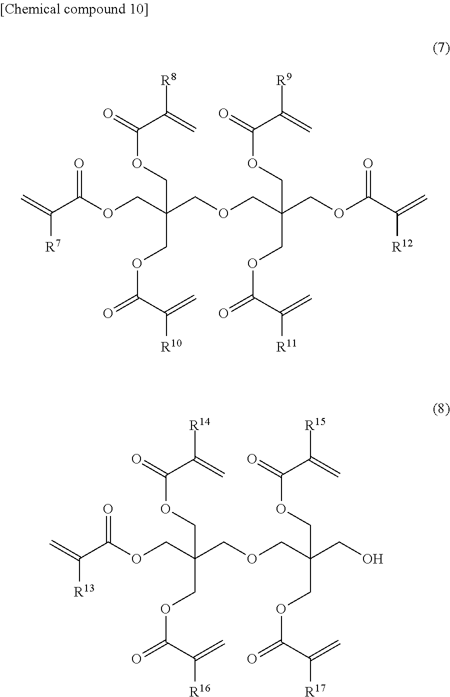

In the formulas (7) and (8), R⁷ to R¹⁷ are each independently a hydrogen atom or a methyl group.

If the radical polymerizable compound (C) contains a compound as represented by the formula (7) and a compound as represented by the formula (8) in a mass ratio as specified above, it can provide a photosensitive resin composition that has high sensitivity even when it is in the form of a thin film with a thickness of 0.5 to 4 μm while ensuring the production of a laminate in which the relief pattern of the organic insulating film (P1) and the metal wire (M2) makes a smaller angle.

The total mass of the compound represented by the formula (7) and the compound represented by the formula (8) is preferably 10 to 50 parts by mass relative to 100 parts by mass of the radical polymerizable compound (C), and if it is in this range, it serves to provide a photosensitive resin composition having high sensitivity and a laminate having high chemical resistance and high heat resistance.

The content of the radical polymerizable compound (C) is preferably 5 to 200 parts by mass relative to 100 parts by mass of the alkali soluble resin (A), and from the viewpoint of compatibility, it is more preferably 5 to 150 parts by mass. If the content of the radical polymerizable compound (C) is 5 parts by mass or more relative to 100 parts by mass of the alkali soluble resin (A), it serves to reduce the elution of the light-exposed region during development and produce a resin composition that is low in residual film rate after development. If the content of the radical polymerizable compound (C) is 200 parts by mass or less relative to 100 parts by mass of the alkali soluble resin (A), it serves to suppress the whitening of the film during film formation.

The term “thermally crosslinkable compound (D)” refers to a compound that is other than the radical polymerizable compound (C) and that has a crosslinkable group capable of bonding with resin or similar molecules. Here, a compound having both a radical polymerizable group and a thermally crosslinkable group is referred to as radical polymerizable compound (C). The thermally crosslinkable compound (D) may be, for example, a polyfunctional epoxy group-containing compound (D-1) or a polyfunctional alkoxymethyl group-containing compound (D-2). The inclusion of the thermally crosslinkable compound (D) serves to cause a condensation reaction with resin and similar molecules during heat treatment to form a crosslinked structure, thereby leading to a cured product with high chemical resistance. The inclusion of the polyfunctional epoxy group-containing compound (D-1) serves to develop chemical resistance while reducing acid ions, but it tends to reduce the alkali solubility. On the other hand, although serving to realize high chemical resistance, the polyfunctional alkoxymethyl group-containing compound (D-2) tends to contain the formate ion as impurity. Therefore, it is preferable for these compounds to be contained in appropriate amounts.

The content of the thermally crosslinkable compound (D) is preferably 1 to 50 parts by mass relative to 100 parts by mass of the alkali soluble resin (A). It is preferable for the thermally crosslinkable compound (D) to include a polyfunctional epoxy group-containing compound (D-1) and a polyfunctional alkoxymethyl group-containing compound (D-2), wherein the polyfunctional epoxy group-containing compound (D-1) accounts for 5 to 30 parts by mass relative to 100 parts by mass of the alkali soluble resin (A) and the polyfunctional alkoxymethyl group-containing compound (D-2) accounts for 1 to 10 parts by mass relative thereto.

When the contents of the polyfunctional epoxy group-containing compound (D-1) and the polyfunctional alkoxymethyl group-containing compound (D-2) are in these ranges, a laminate with high chemical resistance can be produced while suppressing the content of acid ions.

Examples of the polyfunctional epoxy group-containing compound (D-1) include alkylene glycol type epoxy resins such as bisphenol A type epoxy resin, bisphenol F type epoxy resin, and propylene glycol diglycidyl ether; polyalkylene glycol type epoxy resins such as polypropylene glycol diglycidyl ether; and epoxy-containing silicones such as polymethyl(glycidyloxypropyl)siloxane.

More specific examples include TECHMORE VG3101L (trade name, manufactured by Printec, Inc.), TEPIC (registered trademark) VL, TEPIC (registered trademark) UC (trade names, manufactured by Nissan Chemical Corporation), Epiclon (registered trademark) 850-S, Epiclon (registered trademark) HP-4032, Epiclon (registered trademark) HP-7200, Epiclon (registered trademark) HP-820, Epiclon (registered trademark) HP-4700, Epiclon (registered trademark) EXA-4710, Epiclon (registered trademark) HP-4770, Epiclon (registered trademark) EXA-859CRP, Epiclon (registered trademark) EXA-1514, Epiclon (registered trademark) EXA-4880, Epiclon (registered trademark) EXA-4850-150, Epiclon (registered trademark) EXA-4850-1000, Epiclon (registered trademark) EXA-4816, Epiclon (registered trademark) EXA-4822 (all trade names, manufactured by DIC Corporation), RIKARESIN (registered trademark) BEO-60E (trade name, manufactured by New Japan Chemical Co., Ltd.), EP-4003S and EP-4000S (both trade names, manufactured by ADEKA Corporation).

Specific examples of the polyfunctional alkoxymethyl group-containing compound (D-2) include those having two functional groups such as DM-B125 X-F, 46DMOC, 46DMOIPP, 46DMOEP (all trade names, manufactured by Asahi Organic Chemicals Industry Co., Ltd.), DML-MBPC, DML-MBOC, DML-OCHP, DML-PC, DML-PCHP, DML-PTBP, DML-34X, DML-EP, DML-POP, DML-OC, dimethylol-Bis-C, dimethylol-BisOC-P, DML-BisOC-Z, DML-BisOCHP-Z, DML-PFP, DML-PSBP, DML-MB25, DML-MTrisPC, DML-Bis25X-34XL, DML-Bis25X-PCHP (all trade names, manufactured by Honshu Chemical Industry Co., Ltd.), Nikalac (registered trademark) MX-290 (trade name, manufactured by Sanwa Chemical Co., Ltd.), B-a type benzoxazine, B-m type benzoxazine (both trade names, manufactured by Shikoku Chemicals Corporation), 2,6-dimethoxymethyl-4-t-butylphenol, 2,6-dimethoxymethyl-p-cresol, 2,6-diacetoxymethyl-p-cresol; those having three functional groups such as TriML-P, TriML-35XL, TriML-TrisCR-HAP (all trade names, manufactured by Honshu Chemical Industry Co., Ltd.); those having four functional groups such as TM-BIP-A (trade name, manufactured by Asahi Organic Chemicals Industry Co., Ltd.), TML-BP, TML-HQ, TML-pp-BPF, TML-BPA, TMOM-BP (all trade names, manufactured by Honshu Chemical Industry Co., Ltd.), Nikalac (registered trademark) MX-280, Nikalac (registered trademark) MX-270 (both trade names, manufactured by Sanwa Chemical Co., Ltd.); and those having six functional groups such as HML-TPPHBA, HML-TPHAP, HMOM-TPPHBA, HMOM-TPHAP (all trade names, manufactured by Honshu Chemical Industry Co., Ltd.), Nikalac (registered trademark) MW-390, Nikalac (registered trademark) MW-100LM (both trade names, manufactured by Sanwa Chemical Co., Ltd.).

In addition, the photosensitive resin composition may also contain a generally known surface active agent, adhesion improver, etc., which can ensure enhanced wetting and contact with the substrate.

The photosensitive resin composition further contains a solvent. Examples of the organic solvent include aromatic hydrocarbons as well as aprotic polar solvents such as N-methyl-2-pyrrolidone, γ-butyrolactone, γ-valerolactone, δ-valerolactone, N,N-dimethylformamide, N,N-dimethylacetamide, dimethylsulfoxide, 1,3-dimethyl-2-imidazolidinone, N,N′-dimethylpropylene urea, N,N-dimethylisobutyric acid amide, N,N-dimethylpropanamide, 3-methoxy-N,N-dimethylpropanamide, and N,N-dimethyllactamide. The photosensitive resin composition may contain two or more of these.

The solid content and viscosity of the photosensitive resin composition is adjusted by changing the content of the above solvent. To form a good organic insulating film (P1), the photosensitive resin composition preferably has a solid content of 30 to 50 mass % and preferably has a viscosity of 50 to 300 mPa·s. Here, the solid content refers to the mass percentage of all compounds other than the solvent relative to 100 mass % of the photosensitive resin composition. Accordingly, it is preferable for the aforementioned solvent to account for 50 to 70 mass % relative to 100 mass % of the photosensitive resin composition. If its content is in this range, it serves to form a relief pattern of the organic insulating film (P1) having a uniform thickness in the range of 0.5 to 4 μm.

The photosensitive resin composition to adopt to form the organic insulating film (P1) may be a photosensitive resin composition as described above, but may also be a photosensitive resin composition that contains a photoacid generator as the cationic polymerization initiator and an epoxy compound or oxetane compound as the cationic polymerizable compound as long as they do not cause increased ion elution from the organic film.

The method for manufacturing a laminate according to the present invention includes the following steps in that order:
a step (1) for forming a metal wire (M1) on a piezoelectric substrate,
a step (2) for applying a photosensitive resin composition over the piezoelectric substrate and the metal wire (M1) and drying it by heating at 80° C. to 130° C. to form a photosensitive resin film on the substrate,
a step (3) for exposing the photosensitive resin film to light through a mask to an exposure dose of 150 to 2,000 mJ/cm²,
a step (4) for heating the light-exposed photosensitive resin film at 80° C. to 130° C.,
a step (5) for removing the unexposed regions with an alkaline aqueous solution to develop the photosensitive resin film,
a step (6) for heat-treating the developed photosensitive resin film at 200° C. to 280 to form a relief pattern of an organic insulating film (P1), and
a step (7) for forming a metal wire (M2) on the piezoelectric substrate and the organic insulating film (P1).

The method for manufacturing the laminate according to the present invention is described in detail below.

In a step (1), a metal wire (M1) is formed on a piezoelectric substrate. The metal wire (M1) is formed by, for example, disposing a sputtered film of titanium or the like as a seed layer on the piezoelectric substrate, followed by disposing an additional sputtered film of aluminum or copper. A metal wire is formed by removing the metal in the openings using a photosensitive resist or by growing aluminum or copper in the openings in the photosensitive resist, followed by removing the resist with a stripping solution and removing the seed layer with an etching solution.

Next, in the step (2), the photosensitive resin composition is applied over the piezoelectric substrate and the metal wire (M1) by spin coating or the like and dried by heating at 80° C. to 130° C. using a hot plate to form a photosensitive resin film on the substrate. Good methods for its application include spray coating, roll coating, screen printing, and other coating techniques using a blade coater, die coater, calender coater, meniscus coater, bar coater, roll coater, comma roll coater, gravure coater, screen coater, slit die coater, or the like.

Next, in the step (3), the photosensitive resin film on the metal wire (M1) is exposed to light through a mask using an aligner, stepper device, or the like. As the actinic ray for light exposure, it is preferable to use the i-line (365 nm), h-line (405 nm), or g-line (436 nm) of mercury lamps. To realize sufficient curing of the photosensitive resin film while suppressing the temperature rise of the photosensitive resin film and the substrate, it is exposed to an exposure dose of 150 to 2,000 mJ/cm².

Next, in the step (4), the light-exposed photosensitive resin film is heated at 80° C. to 130° C. This step serves to promote the curing reaction in the exposed region of the photosensitive resin film. In the case of using a positive type photosensitive resin composition that contains a naphthoquinone diazide compound (E) or the like, the step (4) may be omitted.

Next, in the step (5), the photosensitive resin film is developed to remove the unexposed region with an alkaline aqueous solution. Preferable developers include aqueous solutions of alkaline compounds such as tetramethyl ammonium hydroxide, diethanol amine, diethyl aminoethanol, sodium hydroxide, potassium hydroxide, sodium carbonate, potassium carbonate, trimethyl amine, diethyl amine, methyl amine, dimethyl amine, dimethylaminoethyl acetate, dimethylaminoethanol, dimethylaminoethyl methacrylate, cyclohexyl amine, ethylene diamine, and hexamethylene diamine.

Next, in the step (6), the developed photosensitive resin film is heat-treated at 200° C. to 280° C. to form a relief pattern of the organic insulating film (P1). It is preferable for the heat treatment to be carried out using an oven in a nitrogen atmosphere. For example, a good heat treatment procedure is to heat the film at a rate of 4° C./min from 50° C., heat-treat it at 140° C. for 30 minutes, heat it again at a rate of 4° C./min, and heat-treat it at 200° C. for 60 minutes. To reduce damage to the substrate while ensuring good organic film properties, it is preferable to perform heat treatment at 200° C. to 350° C., more preferably 200° C. to 280° C.

Finally, in the step (7), a metal wire (M2) is formed on the piezoelectric substrate and the organic insulating film (P1). The metal wire (M1) and the metal wire (M2) on the piezoelectric substrate intersect each other with the relief pattern of the organic insulating film (P1) interposed in between, and this permits flexible wire design without short-circuiting. The formation of the metal wire (M2) is carried out in the same manner as in the step (1).

In the step (5), the difference between the thickness of the light-exposed region of the photosensitive resin film after development for 80 seconds and that after development for 140 seconds is preferably 0.20 μm or less. If the difference between the thickness of the light-exposed region of the photosensitive resin film after development for 80 seconds and that after development for 140 seconds is 0.20 μm or less, it ensures the production of a laminate having a uniform thickness and being high in chemical resistance and insulation efficiency.

The method for manufacturing the laminate according to the present invention may include a step (5-1) between the step (5) and the step (6) in order to heat the developed photosensitive resin film from a temperature of 100° C. or less to a temperature of 150° C. to 200° C. at a heating rate of 10° C./min or more. The heating at 150° C. to 200° C. acts to soften the end portion of the relief pattern of the photosensitive resin film, and accordingly, the angle between the plane where the piezoelectric substrate is in contact with the metal wire (M1) and the plane where the relief pattern of the organic insulating film (P1) is in contact with the metal wire (M2) can be decreased. To achieve a high heating rate during the heating, it is preferable to place the photosensitive resin film having a temperature below 100° C. on a hot plate heated at 150° C. to 200° C. One typical procedure is to place the developed photosensitive resin film on a hot plate at 170° C., heat it for 5 minutes, and then cool it to room temperature.

Furthermore, a step (5-2) for exposing the developed photosensitive resin film to light to an exposure dose of 1,000 to 3,000 mJ/cm² may be added between the step (5) and the step (6). Part of the oxime based photopolymerization initiator (B) can remain undecomposed in the cured film during the light exposure in the step (3), and it can act as a source of acid ion generation under high temperature and high humidity conditions. If the step (5-2) is included, the undecomposed portions of the oxime based photopolymerization initiator (B) that are left undecomposed after the exposure in the step (3) are decomposed, thereby reducing the acid ion elution quantity of the laminate. To suppress the temperature rise of the substrate, the exposure dose is preferably 1,000 to 2,000 mJ/cm².

In the case where both the step (5-1) and the step (5-2) are included, either of the step (5-1) and the step (5-2) may be performed first.

The laminate according to the present invention can be suitably used as the substrate for a hollow structure. The hollow structure according to the present invention includes the laminate, a hollow structure support member (P2), and a hollow structure roof member (P3). The hollow structure support member (P2) and the hollow structure roof member (P3) are preferably organic films that contain at least one alkali soluble resin selected from the group consisting of polyimide, polybenzoxazole, polyamide, precursors thereof, and copolymers thereof. The inclusion of these resins serves to form a hollow structure having high heat resistance.

For the hollow structure, the total ion elution quantity of the organic insulating film (P1) with a thickness of 0.5 to 4 μm, the hollow structure support member (P2), and the hollow structure roof member (P3) is preferably 2,000 ppm or less, wherein the organic insulating film (P1) with a thickness of 0.5 to 4 μm, the hollow structure support member (P2), and the hollow structure roof member (P3) are examined separately by the ion elution quantity measurement method described above.

When evaluating the hollow structure by the ion elution quantity measurement method, the term “organic film” refers to the organic insulating film (P1) with a film thickness of 0.5 to 4 μm, the hollow structure support member (P2), or the hollow structure roof member (P3).

If the total ion elution quantity of the organic insulating film (P1), the hollow structure support material (P2), and the hollow structure roof material (P3) is 2,000 ppm or less, it serves to suppress the corrosion of the metal wires inside the hollow structure.

An electronic component according to the present invention includes a hollow structure as described above. The inclusion of a hollow structure serves to produce an electronic component with suppressed corrosion and degradation. Examples of such an electronic component containing a hollow structure include MEMS.

As in the case of the organic insulating film (P1), the hollow structure support member (P2) and the hollow structure roof member (P3) can be formed by curing a photosensitive resin composition. The hollow structure support member (P2) preferably has a film thickness of 5 to 20 μm, and the photosensitive resin composition used to produce the hollow structure support member (P2) is preferably in a liquid or sheet form. When the photosensitive resin composition used to produce the hollow structure support member (P2) is in a liquid form, its solid content is preferably 50 to 60 mass %, and its viscosity is preferably 500 to 3,000 mPa·s. If they are in these ranges, it serves for the production of a hollow structure support member (P2) that has a uniform film thickness of 5 to 20 μm.

The hollow structure roof member (P3) preferably has a film thickness of 10 to 50 μm, and the photosensitive resin composition used to produce the hollow structure roof member (P3) is preferably in the form of a sheet. Such a photosensitive sheet is produced by the method described below.

Good methods to use to spread the photosensitive resin composition to produce the hollow structure support member (P2) include spin coating using a spin coater, spray coating, roll coating, screen printing, and coating techniques using a blade coater, die coater, calender coater, meniscus coater, bar coater, roll coater, comma roll coater, gravure coater, screen coater, slit die coater, or the like. Then, the substrate coated therewith is dried to form a photosensitive resin film. Drying is preferably performed using an oven, hot plate, infrared light at 50° C. to 150° C. for 1 minute to several hours.

When the photosensitive resin composition designed to produce the hollow structure support member (P2) and the hollow structure roof member (P3) is to be used as a photosensitive sheet, the photosensitive resin composition is applied over a substrate and dried to remove the organic solvent, thereby providing a photosensitive sheet.

For example, a PET film can be used as the substrate to be coated with the photosensitive resin composition. In the case where a photosensitive sheet is used by attaching it to a substrate such as silicon wafer, wherein the PET film used as substrate has to be separated by peeling, it is preferable to adopt a PET film having a surface coated with a release agent such as silicone resin because it allows the photosensitive sheet and the PET film to be separated easily.

Good methods for applying the photosensitive resin composition to a PET film include screen printing and the use of a spray coater, bar coater, blade coater, die coater, spin coater, etc. Good methods to remove the organic solvent include heating by an oven or hot plate, vacuum drying, and the use of infrared ray and electromagnetic waves such as microwave for heating. Here, if the removal of the organic solvent failed to be carried out completely, the cured product resulting from the subsequent curing step may be in an uncured state or has poor thermal properties. The thickness of the PET film is not particularly limited, but it is preferably in the range of 30 to 80 μm from the viewpoint of workability. In addition, the surface of the photosensitive sheet may also have a cover film attached thereon to protect the surface from dust etc. in the air. Furthermore, in the case where the photosensitive resin composition is so low in solid content that it cannot serve to produce a photosensitive sheet with a desired thickness, two or more photosensitive sheets may be combined together after removing the organic solvent therefrom.

In the case where a photosensitive sheet produced by the above method is attached to a separate substrate, a laminating device such as roll laminator and vacuum laminator may be used, or it may be attached manually to a substrate heated on a hot plate using a rubber roller. After attaching it to a substrate, the PET film is peeled off after sufficient cooling.

The photosensitive resin film produced by applying and drying a liquid photosensitive resin composition on a substrate, or the photosensitive sheet formed by lamination on a substrate, is then cured by the same steps (3) to (6) as explained in the description of the method for production of a laminate.

The laminate and the hollow structure according to the present invention are described below with reference to figures.

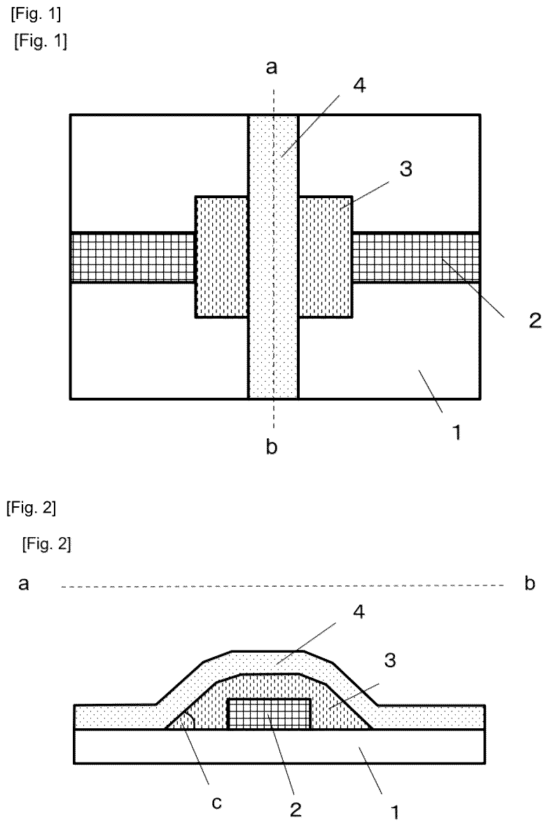

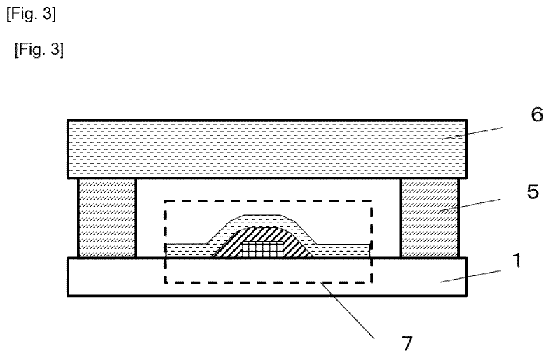

FIG. 1 is a diagram showing the laminate according to the present invention looking from above the piezoelectric substrate 1. The metal wire (M2) 4 is disposed on the same piezoelectric substrate 1 as the metal wire (M1) 2, but it is insulated by the organic insulating film (P1) 3 from the metal wire (M1) 2 in the area where it intersects the metal wire (M1) 2. FIG. 2 shows a cross section cut along the line connecting a and b and perpendicular to the piezoelectric substrate. The angle formed between the plane where the piezoelectric substrate is in contact with the metal wire (M1) and the plane where the relief pattern of the organic insulating film (P1) is in contact with the metal wire (M2) is the taper angle of the relief pattern of the organic insulating film (P1) on the piezoelectric substrate, and c in FIG. 2 denotes this angle. FIG. 3 shows a hollow structure having the hollow structure support member 5 and the hollow structure roof member 6. The laminate according to the present invention is disposed in the part denoted by 7.

### EXAMPLES

The present invention will be described below with reference to examples, though the present invention is not limited to these examples.

First, the evaluation procedures that were used for the examples and comparative examples are described.

### (1) Evaluation of Ion Elution Quantity and Conductivity of Organic Insulating Film (P1)

First, a cured product of the organic insulating film (P1) was prepared as follows.

A photosensitive varnish was spread over a PET film with a thickness of 38 μm using a comma roll coater, dried at 80° C. for 8 minutes, and laminated with a 10 μm thick PP film as protection film to prepare a photosensitive sheet. The thickness of the photosensitive sheet was adjusted to 30 μm.

The photosensitive sheet was attached using a rubber roller to a PTFE film heated at 120° C. on a hot plate, and then the PET film was peeled off. Using an inert oven, the photosensitive sheet on the PTFE film was heated to 250° C. at a heating rate of 3.5° C. per minute in a nitrogen flow with an oxygen concentration of 20 ppm or less, followed by performing heat treatment at 250° C. for 1 hour to provide a cured product.

Then, the cured product was peeled off from the PTFE film and subjected to cryogenic grinding using liquid nitrogen. Then, a 2.0 g specimen was weighed off and put along with 20 g of pure water in an air-tight, pressure-resistant decomposition container made of PTFE and stored under the conditions of 121° C., 100% humidity, and 2 atm for 20 hours using a highly accelerated life test apparatus (saturated type pressure cooker test apparatus). The supernatant of the extract was filtered through a 0.45 μm membrane filter to prepare a test liquid.

Next, according to the ion chromatography method described in the Japanese Industrial Standard JIS K 0127 (2013) “General rules for ion chromatography”, standard solutions of the formate ion, acetate ion, propionate ion, and sulfate ion were introduced separately into an ion chromatography analyzer (ICS-3000, manufactured by Dionex Corporation), and working curves were prepared. Then, 25 μL of the test liquid was poured, and the concentration of the formate ion, acetate ion, propionate ion, or sulfate ion was determined from the observed peak and the working curve, followed by calculating the total mass of the eluted ions. It was rated as A if the ion elution quantity determined as the mass of the eluted ions relative to the mass of the organic film was 500 ppm or less, rated as B if it was more than 500 ppm and 2,000 ppm or less, or rated as C if it was more than 2,000 ppm. In addition, it was rated as A if the conductivity of the test solution measured by the ion chromatography analyzer was 300 μS/cm or less, rated as B if it was more than 300 μS/cm and 500 μS/cm or less, or rated as C if it was more than 500 μS/cm.

### (2) Evaluation of Organic Insulating Film (P1) for Heat Resistance

A sample of 15 mg was weighed off from the cured product peeled from the PTFE film in the paragraph (1), and it was heated from 25° C. to 400° C. at a rate of 10° C./min using a thermogravimetric analyzer (TGA-50, manufactured by Shimadzu Corporation increase.), followed by making an evaluation for heat resistance. The sample was rated as A if the temperature at which the weight decreased by 5% from the initial weight measured before heating was 350° C. or more, rated as B if it was less than 350° C. and 300° C. or more, or rated as C if it was less than 300° C.

### (3) Evaluation of Laminate

### (3-1) Preparation of Laminate

On a lithium tantalate substrate, a copper sputtered film with a thickness of 1 μm was formed by an electrolytic plating procedure that uses a patterned resist formed by sputtering on a titanium base with a thickness of 50 nm. As the metal wire (M1), a pattern containing Cu wires each having a width of 30 μm and spaced at intervals of 100 μm was formed on the sputtered film by etching through a resist pattern.

A photosensitive varnish with a viscosity of 50 to 300 mPa·s was applied on the lithium tantalate substrate and the metal wire (M1) using a spin coater, and it was baked at 120° C. for 3 minutes using a hot plate to prepare a photosensitive resin film. Then, it was exposed to light to 300 mJ/cm² using a ghi aligner through a mask having a pattern of squares with sides of 90 μm and spaced at intervals of 40 μm. After exposure, its development was carried out for 100 seconds using a 2.38 mass % aqueous solution of tetramethylammonium hydroxide (TMAH), followed by rinsing with pure water. As a result, a 2.0 to 4.0 μm thick pattern in which there remain squares with sides of 90 μm was formed on the metal wire (M1). It was heated to 250° C. at a heating rate of 3.5° C. per minute in a nitrogen flow with an oxygen concentration of 20 ppm or less using an inert oven, followed by performing heat treatment at 250° C. for 1 hour, thereby forming a relief pattern of the organic insulating film (P1).

Using the sputtering technique, titanium was sputtered to a thickness of 50 μm on the lithium tantalate substrate, the metal wire (M1), and the relief pattern of the organic insulating film (P1), followed by performing electrolytic plating though a patterned resist to produce, as metal wire (M2), a pattern of Cu wires with a thickness of 2 μm each having a width of 30 μm and spaced at intervals of 100 μm in such a manner that they intersect the metal wire (M1) with the relief pattern of the organic insulating film (P1) interposed in between. In this way, a laminate having a piezoelectric substrate and a wiring pattern disposed thereon in which a metal wire (M1) and a metal wire (M2) intersected each other in a grid pattern with a relief pattern of an organic insulating film (P1) interposed in between was produced.

### (3-2) Evaluation of Organic Insulating Film (P1) for Taper Angle

The laminate produced in the paragraph (3-1) was diced perpendicular to the lithium tantalate substrate using a dicing device, and the angle formed between the plane where the lithium tantalate substrate was in contact with the metal wire (M1) and the plane where the relief pattern of the organic insulating film (P1) was in contact with the metal wire (M2) was observed and evaluated as the taper angle under a scanning electron microscope (S-4800, manufactured by Hitachi Ltd.). A sample was rated as A if the taper angle was 20° to 50°, rated as B if it was more than 50° and 60° or less, and rated as C if it was less than 20° or more than 60°.

### (3-3) Evaluation of Organic Insulating Film (P1) for Variation in Development Loss of Film Thickness

In the paragraph (3-1), the difference in the film thickness of the exposed region between before and after development of the photosensitive resin film performed for a development time of 80 seconds (ΔT₈₀) (film thickness before development−film thickness after development) and the difference in the film thickness of the exposed region between before and after development performed for 140 seconds (ΔT₁₄₀) (film thickness before development−film thickness after development) were measured, and the difference between them (ΔT₁₄₀−ΔT₈₀) was calculated to represent the variation in development loss of film thickness. A sample was rated as A if the absolute value of the variation in development loss of film thickness was 0.2 μm or less, rated as B if it was more than 0.2 μm and 0.6 μm or less, and rated as C if it was more than 0.6 μm.

### (3-4) Chemical Resistance of Organic Insulating Film (P1)

The laminate prepared in the paragraph (3-1) was immersed in N-methylpyrrolidone at 70° C. for 30 minutes. The difference of “thickness of organic insulating film (P1) after immersion−thickness of organic insulating film (P1) before immersion” was measured. A sample rated as A if it was 0.2 μm or less, rated as B if it was more than 0.2 μm and 0.5 μm or less, and rated as C if it was more than 0.5 μm.

### (4) Evaluation of Hollow Structure

### (4-1) Measurement of Ion Elution Quantity of Hollow Structure Support Member (P2) and Hollow Structure Roof Member (P3)

First, a cured product of the hollow structure support member (P2) was prepared as follows. A photosensitive varnish was spread over a PET film with a thickness of 38 μm using a comma roll coater, dried at 80° C. for 8 minutes, and laminated with a 10 μm thick PP film as protection film to prepare a photosensitive sheet. The thickness of the photosensitive sheet was adjusted to 30 μm.

The photosensitive sheet was attached using a rubber roller to a PTFE film heated at 120° C. on a hot plate, and then the PET film was peeled off. Using an inert oven, the photosensitive sheet on the PTFE film was heated to 200° C. at a heating rate of 3.5° C. per minute in a nitrogen flow with an oxygen concentration of 20 ppm or less, followed by performing heat treatment at 200° C. for 1 hour to provide a cured product.

A cured product of the hollow structure roof member (P3) was produced using a photosensitive sheet by the same procedure as used for the cured product of the hollow structure support member (P2).

For each of the cured products of the hollow structure support member (P2) and the hollow structure roof member (P3), the ion elution quantity was measured in the same manner as in the paragraph (1).

### (4-2) Formation of Hollow Structure

A photosensitive varnish was applied with a spin coater to the laminate produced in the paragraph (3-1) and baked at 120° C. for 3 minutes on a hot plate to produce a prebaked film. Then, it was exposed to light to 500 mJ/cm² using a ghi aligner through a mask having a grid-like pattern with a width of 30 μm and spaced at intervals of 500 μm. After exposure, its development was carried out for 150 seconds using a 2.38 mass % aqueous solution of tetramethylammonium hydroxide (TMAH), followed by rinsing with pure water. The developed film obtained had a 10 μm thick pattern in which there remained a grid having a width of 30 μm and spaced at intervals of 500 μm. The developed film was heated to 200° C. at a heating rate of 3.5° C. per minute in a nitrogen flow with an oxygen concentration of 20 ppm or less using an inert oven, followed by performing heat treatment at 200° C. for 1 hour, thereby forming a hollow structure support member (P2).

Next, it was laminated with a photosensitive sheet using a laminating device (VTM-200M, manufactured by Takatori Corporation) under the conditions of a stage temperature of 80° C., roll temperature of 80° C., vacuum degree of 150 Pa, lamination speed of 5 mm/s, and lamination pressure of 0.2 MPa. After exposing it to light to 500 mJ/cm² using a ghi aligner, it was heated to 200° C. at a heating rate of 3.5° C. per minute in a nitrogen flow with an oxygen concentration of 20 ppm or less using an inert oven, followed by performing heat treatment at 200° C. for 1 hour to form a hollow structure having a hollow structure roof member (P3).

### (4-3) Evaluation of Hollow Structure for Corrosion Resistance

The hollow structure formed in the paragraph (4-2) was stored for 100 hours under the conditions of a temperature of 121° C., humidity of 100%, and pressure of 2 atm in a highly accelerated life test apparatus, and the hollow part was cut using a dicing device. The cross section of the copper plating on the substrate was polished using a cross section polisher (IB-09010CP, manufactured by JEOL Ltd.), and then, the boundary between the metal wire (M1) and the organic insulating film (P1) was observed using a scanning electron microscope (S-4800, manufactured by Hitachi Ltd.). The thickness of the copper oxide layer formed on the metal wire (M1) was measured. A sample was rated as A if its thickness was 50 nm or less, rated as B if it was more than 50 nm and less than 150 nm, and rated as C if it was 150 nm or more.

Listed below are abbreviations and structures of the compounds used in Examples and Comparative examples given below.

### (Acid Dianhydride)

ODPA: 3,3′,4,4′-diphenyl ether tetracarboxylic dianhydride

### (Diamine)

BAHF: 2,2-bis(3-amino-4-hydroxyphenyl)hexafluoropropane
SiDA: 1,1,3,3-tetramethyl-1,3-bis(3-aminopropyl)disiloxane

### (End Capping Agent)

MAP: 3-aminophenol

### (Solvent)

NMP: N-methyl-2-pyrrolidone
GBL: γ-butyrolactone

### (Oxime Based Photopolymerization Initiator)

PBG-305 (trade name, manufactured by Changzhou Tronly New Electronic Materials Co., Ltd., a compound as represented by formula (1))
NCI-831 (Adeka ARKLS, trade name, manufactured by ADEKA Corporation, a compound as represented by formula (2))
OXE-02 (IRGACURE, trade name, manufactured by Ciba Specialty Chemicals Inc., a compound as represented by formula (2))

### (Radical Polymerizable Compound)

M-315 (Aronix, trade name, manufactured by Toagosei Co., Ltd.)
DPHA: dipentaerythritol hexaacrylate (a compound as represented by formula (3))
DPPA: dipentaerythritol pentaacrylate (a compound as represented by formula (4))

### (Thermal Crosslinking Compound)

### Polyfunctional Epoxy Group-Containing Compound (D-1):

VG-3101L (TECHMORE VG3101L, trade name, manufactured by Printec, Inc.)
TEPIC-VL (trade name, manufactured by Nissan Chemical Corporation)
157s70 (jER, trade name, manufactured by Mitsubishi Chemical Corporation)

### Polyfunctional Alkoxymethyl Group-Containing Compound (D-2):

HMOM-TPHAP (trade name, manufactured by Honshu Chemical Industry Co., Ltd.)
MW-100LM (NIKALAC MW-100LM, trade name, manufactured by Sanwa Chemical Co., Ltd.)

### (Photoacid Generator (Cationic Polymerization Initiator))

CPI-310B (trade name, manufactured by San-Apro Ltd.)

### (Naphthoquinone Diazide Compound)

naphthoquinone diazide compound A
naphthoquinone diazide compound B

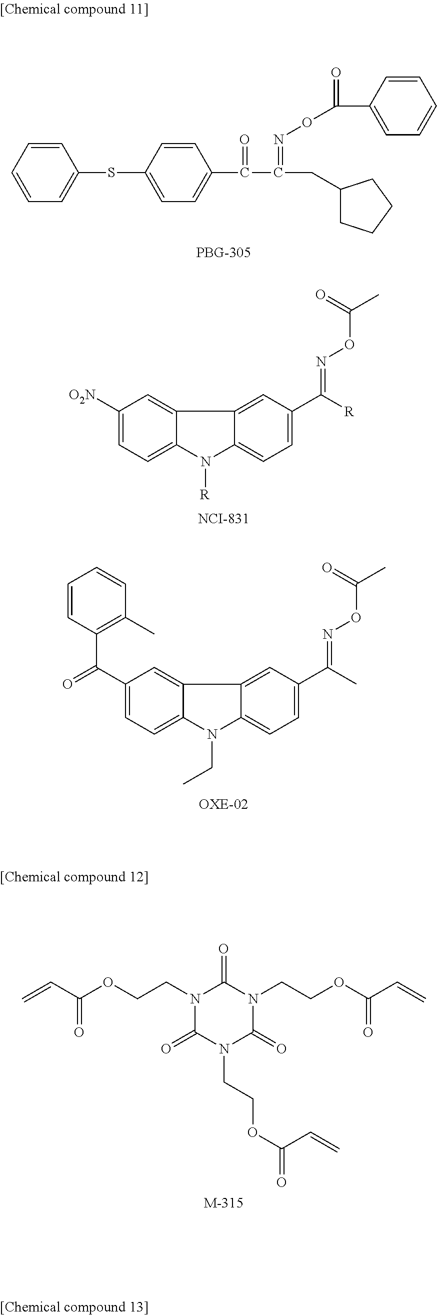

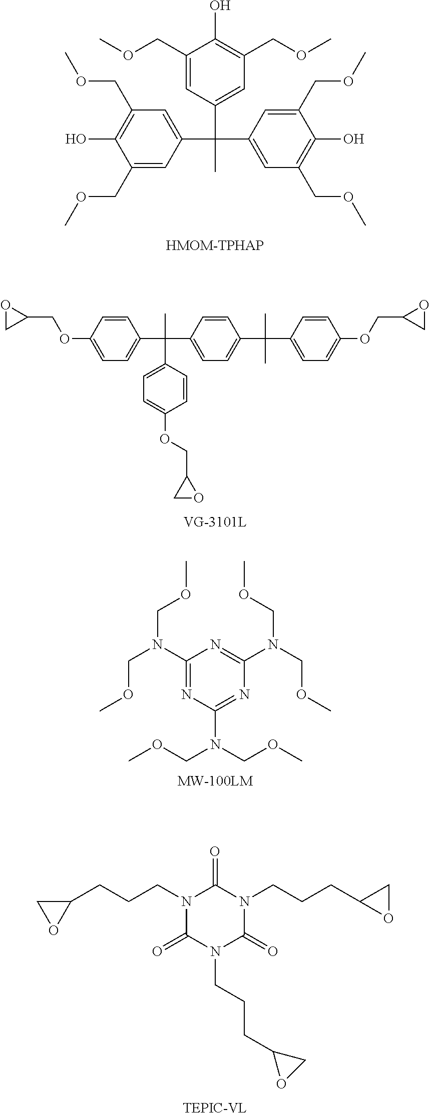

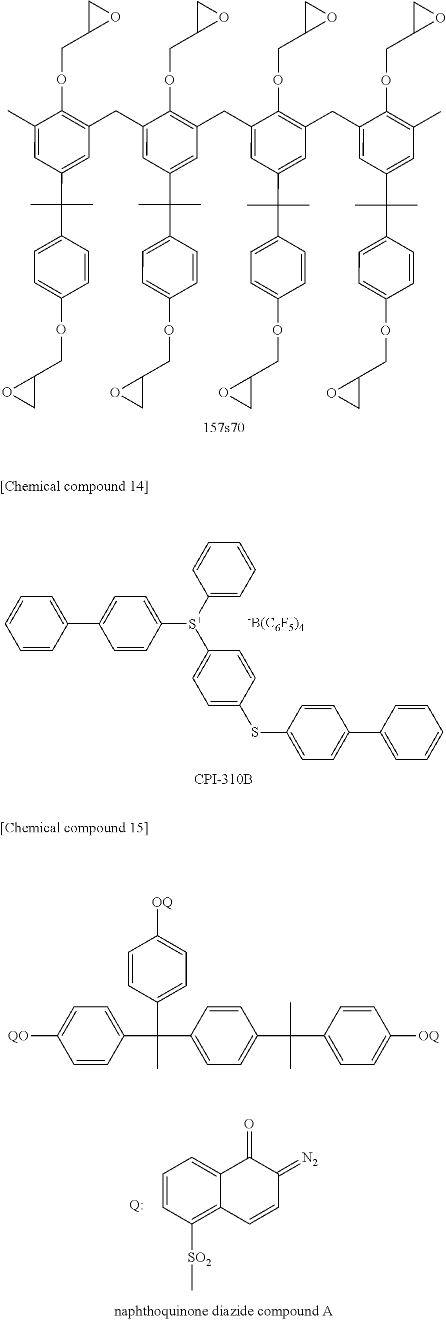

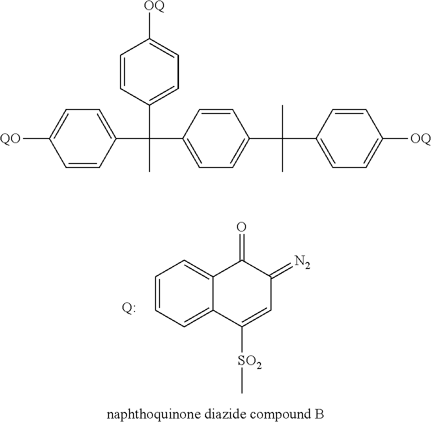

### Synthesis Example 1: Synthesis of Resin A of Alkali Soluble Resin (A)

In a dry nitrogen flow, 15.51 g (0.050 mol) of ODPA and 1.09 g (0.010 mol) of MAP were dissolved in 100 g of NMP. To this solution, 15.57 g (0.043 mol) of BAHF and 0.62 g (0.003 mol) of SiDA were added along with 20 g of NMP and reacted at 60° C. for 1 hour, followed by stirring at 200° C. for 4 hours. After the end of stirring, the solution was poured in 2 L of water to provide a white precipitate. This precipitate was collected by filtration, rinsed with water three times, and dried in a vacuum dryer at 50° C. for 72 hours to provide powder of polyimide resin A.

### Synthesis Example 2: Synthesis of Resin B of Alkali Soluble Resin (A)

A mixed solution was prepared by adding 0.01 mole of sec-butyllithium as initiator to 500 ml of tetrahydrofuran, and a total of 20 g of a mixture of p-t-butoxystyrene and styrene mixed at a molar ratio of 3:1 was added, followed by performing polymerization by stirring for 3 hours. The polymerization was terminated by adding 0.1 mole of methanol to the reaction solution. Then, in order to refine the polymer, the reaction mixture was poured in methanol and the resulting polymer precipitate was dried to provide a white polymer. Subsequently, it was dissolved in 400 ml of acetone and, after adding a small amount of concentrated hydrochloric acid at 60° C., stirred for 7 hours, and poured in water to precipitate a polymer material. Then the p-t-butoxystyrene was deprotected for conversion into hydroxystyrene, followed by washing and drying to provide a refined polyhydroxystyrene resin B, which is a copolymer of p-hydroxystyrene and styrene.

### Synthesis Example 3: Synthesis of Naphthoquinone Diazide Compound A

In a dry nitrogen flow, 21.23 g (0.05 mol) of TrisP-PA (trade name, manufactured by Honshu Chemical Industry Co., Ltd.) and 37.62 g (0.14 mol) of 5-naphthoquinone diazide sulfonyl chloride were dissolved in 450 g of 1,4-dioxane and maintained at room temperature. To this solution, a mixture of 15.58 g (0.154 mol) of triethyl amine with 50 g of 1,4-dioxane was added dropwise while maintaining the system at below 35° C. After the end of dropping, stirring was performed at 30° C. for 2 hours. The resulting triethylamine salt was filtered and the filtrate was poured in water. Then, the precipitate deposited was collected by filtration. The resulting precipitate was dried in a vacuum drying machine to provide a naphthoquinone diazide compound A as represented by the formula given below.

### Synthesis Example 4: Synthesis of Naphthoquinone Diazide Compound B

In a dry nitrogen flow, 21.23 g (0.05 mol) of TrisP-PA and 37.62 g (0.14 mol) of 4-naphthoquinone diazide sulfonyl chloride were dissolved in 450 g of 1,4-dioxane and maintained at room temperature. Using 15.18 g of triethylamine mixed with 50 g of 1,4-dioxane, the same procedure as in Synthesis example 3 was carried out to prepare a naphthoquinone diazide compound B as represented by the formula given below.

### Preparation Example 1 to 25 and 28 to 31: Preparation of Photosensitive Varnishes P1-1 to 29

Materials for photosensitive varnishes shown in Tables 1 and 2 were added and stirred to produce photosensitive varnishes P1-1 to 29 to be used for forming organic insulating films (P1).

TABLE 1

| | | content of each component relative to 100 mass % of photosensitive resin composition (mass %) | | | | | | | |
|---|---|---|---|---|---|---|---|---|---|
| | | | | oxime based photopolymerization initiator | | | | | |
| | | | | (B) | | | radical polymerizable compound (C) | | |
| | | | | compound | | | | compound | compound |
| | | alkali soluble | | represented | compound | | | represented | represented |
| | photosensitive | resin (A) | | by | represented by | | | by | by |
| | varnish or | resin | resin | formula (1) | formula (2) | | | formula (3) | formula (4) |
| | sheet | A | B | PBG-305 | NCI-831 | OXE-02 | M-315 | DPHA | DPPA |
| Preparation | P1-1 | 23.9 | | 2.0 | 0.0 | 0.0 | 13.7 | 0.0 | 0.0 |
| example 1 | | | | | | | | | |
| Preparation | P1-2 | 23.9 | | 2.0 | 0.0 | 0.0 | 13.7 | 0.0 | 0.0 |
| example 2 | | | | | | | | | |
| Preparation | P1-3 | 23.9 | | 2.0 | 0.0 | 0.0 | 13.7 | 0.0 | 0.0 |
| example 3 | | | | | | | | | |
| Preparation | P1-4 | 23.2 | | 3.3 | 0.0 | 0.0 | 13.2 | 0.0 | 0.0 |
| example 4 | | | | | | | | | |
| Preparation | P1-5 | 23.0 | | 3.3 | 0.3 | | 13.1 | 0.0 | 0.0 |
| example 5 | | | | | | | | | |
| Preparation | P1-6 | 23.2 | | 2.7 | 0.5 | | 13.3 | 0.0 | 0.0 |
| example 6 | | | | | | | | | |
| Preparation | P1-7 | 22.3 | | 2.5 | 1.0 | | 12.7 | 0.0 | 0.0 |
| example 7 | | | | | | | | | |
| Preparation | P1-8 | 22.5 | | 1.9 | 1.3 | | 12.8 | 0.0 | 0.0 |
| example 8 | | | | | | | | | |
| Preparation | P1-9 | 20.6 | | 5.2 | 1.3 | | 11.8 | 0.0 | 0.0 |
| example 9 | | | | | | | | | |
| Preparation | P1-10 | 22.3 | | 3.2 | 0.3 | | 12.7 | 0.0 | 0.0 |
| example 10 | | | | | | | | | |
| Preparation | P1-11 | 22.3 | | 3.2 | 0.3 | | 12.7 | 0.0 | 0.0 |
| example 11 | | | | | | | | | |
| Preparation | P1-12 | 22.3 | | 3.2 | 0.3 | | 6.4 | 1.9 | 4.5 |
| example 12 | | | | | | | | | |
| Preparation | P1-13 | 22.3 | | 3.2 | 0.3 | | 6.4 | 3.2 | 3.2 |
| example 13 | | | | | | | | | |
| Preparation | P1-14 | 22.3 | | 3.2 | 0.3 | | 6.4 | 5.1 | 1.3 |
| example 14 | | | | | | | | | |
| Preparation | P1-15 | 25.4 | | 3.6 | 0.4 | | 7.3 | 5.8 | 1.5 |
| example 15 | | | | | | | | | |

| | content of each component relative to 100 mass % of photosensitive resin composition (mass %) | | | | | | | | | |
|---|---|---|---|---|---|---|---|---|---|---|
| | | | | thermally | | other compound | | | | |
| | thermally crosslinkable | | | crosslinkable | | naphtho- | naphtho- | | | |
| | compound | | | compound | | quinone | quinone | | | viscosity of |
| | (D-1) | | | (D-2) | | diazide | diazide | | | photosensitive |
| | VG- | TEPIC- | | HMOM- | MW- | compound | compound | CPI- | solvent | varnish |
| | 3101L | VL | 157s70 | TPHAP | 100LM | A | B | 310B | GBL | (mPa · s) |
| Preparation | 3.4 | | | 0.0 | 0.0 | | | | 57 | 150 |
| example 1 | | | | | | | | | | |
| Preparation | 0.0 | | | 3.4 | 0.0 | | | | 57 | 150 |
| example 2 | | | | | | | | | | |
| Preparation | 0.0 | | | 0.0 | 3.4 | | | | 57 | 150 |
| example 3 | | | | | | | | | | |
| Preparation | 0.0 | | | 0.0 | 3.3 | | | | 57 | 150 |
| example 4 | | | | | | | | | | |
| Preparation | 0.0 | | | 0.0 | 3.3 | | | | 57 | 150 |
| example 5 | | | | | | | | | | |
| Preparation | 0.0 | | | 0.0 | 3.3 | | | | 57 | 150 |
| example 6 | | | | | | | | | | |
| Preparation | 0.0 | | | 3.2 | 1.3 | | | | 57 | 150 |
| example 7 | | | | | | | | | | |
| Preparation | 0.0 | | | 3.2 | 1.3 | | | | 57 | 150 |
| example 8 | | | | | | | | | | |
| Preparation | 0.0 | | | 2.9 | 1.2 | | | | 57 | 150 |
| example 9 | | | | | | | | | | |
| Preparation | 1.3 | | | 3.2 | 0.0 | | | | 57 | 150 |
| example 10 | | | | | | | | | | |
| Preparation | 3.2 | | | 1.3 | 0.0 | | | | 57 | 150 |
| example 11 | | | | | | | | | | |
| Preparation | 3.2 | | | 1.3 | 0.0 | | | | 57 | 150 |
| example 12 | | | | | | | | | | |
| Preparation | 3.2 | | | 1.3 | 0.0 | | | | 57 | 150 |
| example 13 | | | | | | | | | | |
| Preparation | 3.2 | | | 1.3 | 0.0 | | | | 57 | 150 |
| example 14 | | | | | | | | | | |
| Preparation | 3.6 | | | 1.5 | 0.0 | | | | 51 | 300 |
| example 15 | | | | | | | | | | |

TABLE 2

| | | content of each component relative to 100 mass % of photosensitive resin composition (mass %) | | | | | | | |
|---|---|---|---|---|---|---|---|---|---|
| | | | | oxime based photopolymerization | | | | | |
| | | | | initiator (B) | | | radical polymerizable compound (C) | | |
| | | | | compound | compound | | | compound | compound |
| | | alkali soluble | | represented | represented by | | | represented | represented |
| | photosensitive | resin (A) | | by | formula (2) | | | by | by |
| | varnish or | resin | resin | formula (1) | NCI- | OXE- | | formula (3) | formula (4) |
| | sheet | A | B | PBG-305 | 831 | 02 | M-315 | DPHA | DPPA |
| Preparation | P1-16 | 28.6 | 0.0 | 0.0 | 0.0 | 0.0 | 0.0 | 0.0 | 0.0 |
| example 16 | | | | | | | | | |
| Preparation | P1-17 | 33.6 | | 0.0 | 0.0 | 0.0 | 0.0 | 0.0 | 0.0 |
| example 17 | | | | | | | | | |
| Preparation | P1-18 | 28.6 | 0.0 | 0.0 | 0.0 | 0.0 | 0.0 | 0.0 | 0.0 |
| example 18 | | | | | | | | | |
| Preparation | P1-19 | 0.0 | 16.4 | 0.0 | 0.0 | 0.0 | 0.0 | 0.0 | 0.0 |
| example 19 | | | | | | | | | |
| Preparation | P1-20 | 0.0 | 0.0 | 0.0 | 0.0 | 0.0 | 0.0 | 0.0 | 0.0 |
| example 20 | | | | | | | | | |
| Preparation | P1-21 | 0.0 | 15.9 | 3.4 | 0.3 | | 13.8 | 0.0 | 0.0 |
| example 21 | | | | | | | | | |
| Preparation | P1-22 | 22.5 | | 0.0 | 3.2 | 0.0 | 12.8 | 0.0 | 0.0 |
| example 22 | | | | | | | | | |
| Preparation | P1-23 | 22.5 | | 0.0 | 0.0 | 3.2 | 12.8 | 0.0 | 0.0 |
| example 23 | | | | | | | | | |
| Preparation | P1-24 | 22.5 | | 1.3 | 1.9 | | 12.8 | 0.0 | 0.0 |
| example 24 | | | | | | | | | |
| Preparation | P1-25 | 21.5 | | 1.2 | 1.8 | | 12.3 | 0.0 | 0.0 |
| example 25 | | | | | | | | | |
| Preparation | P2-1 | 32.8 | | 3.8 | 0.0 | 0.0 | 18.8 | 0.0 | 0.0 |
| example 26 | | | | | | | | | |
| Preparation | P3-1 | 32.8 | | 3.8 | 0.0 | 0.0 | 18.8 | 0.0 | 0.0 |
| example 27 | | | | | | | | | |
| Preparation | P1-26 | 25.9 | 0.0 | 0.0 | 0.0 | 0.0 | 0.0 | 0.0 | 0.0 |
| example 28 | | | | | | | | | |
| Preparation | P1-27 | 30.8 | 0.0 | 0.0 | 0.0 | 0.0 | 0.0 | 0.0 | 0.0 |
| example 29 | | | | | | | | | |
| Preparation | P1-28 | 24.2 | 0.0 | 0.1 | 0.1 | 0.0 | 13.8 | 0.0 | 0.0 |
| example 30 | | | | | | | | | |
| Preparation | P1-29 | 21.5 | 0.0 | 3.1 | 1.8 | 0.0 | 12.3 | 0.0 | 0.0 |
| example 31 | | | | | | | | | |

| | content of each component relative to 100 mass % of photosensitive resin composition (mass %) | | | | | | | | | |
|---|---|---|---|---|---|---|---|---|---|---|
| | | | | thermally | | | | | | |
| | thermally crosslinkable | | | crosslinkable | | other compound | | | | |
| | compound | | | compound | | naphtho- | naphtho- | | | viscosity of |
| | (D-1) | | | (D-2) | | quinone | quinone | | | photosensitive |
| | VG- | TEPIC- | | HMOM- | MW- | diazide | diazide | CPI- | solvent | varnish |
| | 3101L | VL | 157s70 | TPHAP | 100LM | compound A | compound B | 310B | GBL | (mPa · s) |
| Preparation | 1.6 | 0.0 | 0.0 | 4.1 | 1.6 | 3.9 | 0.0 | 0.0 | 60 | 150 |
| example 16 | | | | | | | | | | |
| Preparation | 1.9 | | | 4.8 | 1.9 | | | | 53 | 300 |
| example 17 | | | | | | | | | | |
| Preparation | 1.6 | 0.0 | 0.0 | 4.1 | 1.6 | 0.0 | 3.9 | 0.0 | 60 | 150 |
| example 18 | | | | | | | | | | |
| Preparation | 0.0 | 16.4 | 0.0 | 0.0 | 0.0 | 0.0 | 0.0 | 1.3 | 55 | 150 |
| example 19 | | | | | | | | | | |
| Preparation | 0.0 | 5.8 | 26.2 | 0.0 | 0.0 | 0.0 | 0.0 | 1.2 | 55 | 150 |
| example 20 | | | | | | | | | | |
| Preparation | 3.4 | 0.0 | 0.0 | 1.4 | 0.0 | 0.0 | 0.0 | 0.0 | 57 | 150 |
| example 21 | | | | | | | | | | |
| Preparation | 0.0 | | | 1.3 | 3.2 | | | | 57 | 150 |
| example 22 | | | | | | | | | | |
| Preparation | 0.0 | | | 1.3 | 3.2 | | | | 57 | 150 |
| example 23 | | | | | | | | | | |
| Preparation | 0.0 | | | 1.3 | 3.2 | | | | 57 | 150 |
| example 24 | | | | | | | | | | |
| Preparation | 3.1 | | | 3.1 | 0.0 | | | | 57 | 150 |
| example 25 | | | | | | | | | | |
| Preparation | 0.0 | | | 4.7 | 0.0 | | | | 40 | 2000 |
| example 26 | | | | | | | | | | |
| Preparation | 0.0 | | | 4.7 | 0.0 | | | | 40 | — |
| example 27 | | | | | | | | | | |
| Preparation | 1.5 | 0.0 | 0.0 | 3.7 | 1.5 | 0.0 | 7.1 | 0.0 | 60 | 150 |
| example 28 | | | | | | | | | | |
| Preparation | 1.8 | 0.0 | 0.0 | 4.4 | 1.8 | 0.0 | 1.3 | 0.0 | 60 | 150 |
| example 29 | | | | | | | | | | |
| Preparation | 3.5 | 0.0 | 0.0 | 1.4 | 0.0 | 0.0 | 0.0 | 0.0 | 57 | 150 |
| example 30 | | | | | | | | | | |
| Preparation | 3.1 | 0.0 | 0.0 | 1.2 | 0.0 | 0.0 | 0.0 | 0.0 | 57 | 150 |
| example 31 | | | | | | | | | | |

### Preparation Examples 26: Preparation of Photosensitive Varnish P2-1

Materials for photosensitive varnishes shown in Tables 1 and 2 were added and stirred to produce a photosensitive varnish P2-1 to be used for forming a hollow structure support member (P2).

### Preparation Example 27: Preparation of Photosensitive Sheet P3-1

Materials for photosensitive varnishes shown in Tables 1 and 2 were added and stirred to produce a photosensitive varnish. This photosensitive varnish was spread over a PET film with a thickness of 38 μm using a comma roll coater, dried at 80° C. for 8 minutes, and laminated with a 10 μm thick PP film as protection film to prepare a photosensitive sheet P3-1 to be used for forming a hollow structure roof member (P3).

### Examples 1 to 21

The evaluations (1) to (4) described above were conducted using the photosensitive varnishes P1-1 to 21 as materials for the organic insulating film (P1), using the photosensitive varnish P2-1 as material for the hollow structure support member (P2), and using the photosensitive sheet P3-1 as material for the hollow structure roof member (P3). Combinations of materials and evaluation results are given in Tables 3 and 4.

### Example 22

During the procedure described in the paragraph (2-1) “Preparation of laminate”, heat treatment was performed using a hot plate at 170° C. for 5 minutes after the development of the photosensitive resin film. Except for this, the evaluations (1) to (4) described above were carried out in the same manner as in Examples 1 to 21. Combinations of materials and evaluation results are given in Tables 3 and 4.

### Example 23

During the procedure described in the paragraph (2-1) “Preparation of laminate”, heat treatment was performed using a hot plate at 200° C. for 5 minutes after the development of the photosensitive resin film. Except for this, the evaluations (1) to (4) described above were carried out in the same manner as in Examples 1 to 21. Combinations of materials and evaluation results are given in Tables 3 and 4.

### Example 24

During the procedure described in the paragraph (2-1) “Preparation of laminate”, the entire photosensitive resin film was exposed to light to 2,000 mJ/cm² using a ghi aligner without using a mask after the development of the photosensitive resin film. Except for this, the evaluations (1) to (4) described above were carried out in the same manner as in Examples 1 to 21. Combinations of materials and evaluation results are given in Tables 3 and 4.

### Comparative Examples 1 to 8

The evaluations (1) to (4) described above were conducted using the photosensitive varnishes P1-22 to 29 as materials for the organic insulating film (P1), using the photosensitive varnish P2-1 as material for the hollow structure support member (P2), and using the photosensitive sheet P3-1 as material for the hollow structure roof member (P3). Combinations of materials and evaluation results are given in Tables 3 and 4.

In Comparative examples 6 and 7, the film was dissolved completely during development, making it impossible to produce a laminate.

TABLE 3

| | photo- | photo- | photo- | | | | | | | | |
|---|---|---|---|---|---|---|---|---|---|---|---|
| | sensitive | sensitive | sensitive | | | | | | | | |
| | varnish | varnish | sheet | | | | | | | | |
| | used | used for | used for | (1) evaluation for ion elution quantity and conductivity of organic insulating film (P1) | | | | | | | |
| | for | hollow | hollow | | | (in- | (in- | (in- | (in- | | |
| | organic | structure | structure | | | cluding) | cluding) | cluding) | cluding) | | |
| | insulating | support | roof | ion elution | | acetate | formate | propionate | sulfate | conduc- | |
| | film | member | member | quantity | | ion | ion | ion | ion | tivity | |
| | (P1) | (P2) | (P3) | (ppm) | | (ppm) | (ppm) | (ppm) | (ppm) | (μS/cm) | |
| Example | P1-1 | P2-1 | P3-1 | 105 | A | 50 | 50 | 5 | 0 | 200 | A |
| 1 | | | | | | | | | | | |
| Example | P1-2 | P2-1 | P3-1 | 205 | A | 50 | 150 | 5 | 0 | 350 | B |
| 2 | | | | | | | | | | | |
| Example | P1-3 | P2-1 | P3-1 | 755 | B | 50 | 700 | 5 | 0 | 470 | B |
| 3 | | | | | | | | | | | |
| Example | P1-4 | P2-1 | P3-1 | 755 | B | 50 | 700 | 5 | 0 | 470 | B |
| 4 | | | | | | | | | | | |
| Example | P1-5 | P2-1 | P3-1 | 855 | B | 150 | 700 | 5 | 0 | 500 | B |
| 5 | | | | | | | | | | | |
| Example | P1-6 | P2-1 | P3-1 | 995 | B | 290 | 700 | 5 | 0 | 500 | B |
| 6 | | | | | | | | | | | |
| Example | P1-7 | P2-1 | P3-1 | 1055 | B | 700 | 350 | 5 | 0 | 400 | B |
| 7 | | | | | | | | | | | |
| Example | P1-8 | P2-1 | P3-1 | 1205 | B | 900 | 300 | 5 | 0 | 400 | B |
| 8 | | | | | | | | | | | |
| Example | P1-9 | P2-1 | P3-1 | 1255 | B | 900 | 350 | 5 | 0 | 420 | B |
| 9 | | | | | | | | | | | |
| Example | P1-10 | P2-1 | P3-1 | 355 | A | 150 | 200 | 5 | 0 | 380 | B |
| 10 | | | | | | | | | | | |
| Example | P1-11 | P2-1 | P3-1 | 255 | A | 150 | 100 | 5 | 0 | 300 | A |
| 11 | | | | | | | | | | | |
| Example | P1-12 | P2-1 | P3-1 | 255 | A | 150 | 100 | 5 | 0 | 300 | A |
| 12 | | | | | | | | | | | |
| Example | P1-13 | P2-1 | P3-1 | 255 | A | 150 | 100 | 5 | 0 | 300 | A |
| 13 | | | | | | | | | | | |
| Example | P1-14 | P2-1 | P3-1 | 255 | A | 150 | 100 | 5 | 0 | 300 | A |
| 14 | | | | | | | | | | | |
| Example | P1-15 | P2-1 | P3-1 | 255 | A | 150 | 100 | 5 | 0 | 300 | A |
| 15 | | | | | | | | | | | |
| Example | P1-16 | P2-1 | P3-1 | 605 | B | 50 | 350 | 5 | 200 | 450 | B |
| 16 | | | | | | | | | | | |
| Example | P1-17 | P2-1 | P3-1 | 605 | B | 50 | 350 | 5 | 200 | 450 | B |
| 17 | | | | | | | | | | | |
| Example | P1-18 | P2-1 | P3-1 | 905 | B | 50 | 350 | 5 | 500 | 480 | B |
| 18 | | | | | | | | | | | |
| Example | P1-19 | P2-1 | P3-1 | 1094 | B | 90 | 1000 | 4 | 0 | 500 | B |
| 19 | | | | | | | | | | | |
| Example | P1-20 | P2-1 | P3-1 | 1084 | B | 80 | 1000 | 4 | 0 | 500 | B |
| 20 | | | | | | | | | | | |
| Example | P1-21 | P2-1 | P3-1 | 255 | A | 150 | 100 | 5 | 0 | 320 | B |
| 21 | | | | | | | | | | | |

| | (2) evaluation | | | | | | | | | | | | | |
|---|---|---|---|---|---|---|---|---|---|---|---|---|---|---|
| | for heat | | | | | | | | | (3) evaluation of hollow structure | | | | |
| | resistance of | | | | | | | | | | | total | | |
| | organic | | | | | | | | | | | ion | corrosion | |
| | insulating | | (2) evaluation of laminate | | | | | | | | | elution | resistant | |
| | film | | | | | development | | | | ion | ion | quantity | copper | |
| | (P1) | | | taper | | film loss | | chemical | | elution | elution | of (P1) | oxide | |
| | weight loss | | thickness | angle of | | variation | | resistance | | quantity | quantity | (P2) | layer | |
| | temperature | | of (P1) | (P1) | | of (P1) | | of (P1) | | of (P2) | of (P3) | (P3) | thickness | |
| | (° C.) | | (μm) | (°) | | (μm) | | (μm) | | (ppm) | (ppm) | (ppm) | (μm) | |
| Example | 350 | A | 2.0 | 40 | A | 0.65 | C | 0.42 | B | 200 | 200 | 505 | 50 | A |
| 1 | | | | | | | | | | | | | | |
| Example | 350 | A | 2.0 | 45 | A | 0.70 | C | 0.33 | B | 200 | 200 | 605 | 50 | A |
| 2 | | | | | | | | | | | | | | |
| Example | 350 | A | 2.0 | 45 | A | 0.65 | C | 0.33 | B | 200 | 200 | 1155 | 90 | B |
| 3 | | | | | | | | | | | | | | |
| Example | 350 | A | 2.0 | 60 | B | 0.51 | B | 0.30 | B | 200 | 200 | 1155 | 90 | B |
| 4 | | | | | | | | | | | | | | |
| Example | 350 | A | 2.0 | 70 | C | 0.35 | B | 0.27 | B | 200 | 200 | 1255 | 90 | B |
| 5 | | | | | | | | | | | | | | |
| Example | 350 | A | 2.0 | 70 | C | 0.30 | B | 0.22 | B | 200 | 200 | 1395 | 100 | B |
| 6 | | | | | | | | | | | | | | |
| Example | 350 | A | 2.0 | 70 | C | 0.30 | B | 0.21 | B | 200 | 200 | 1455 | 80 | B |
| 7 | | | | | | | | | | | | | | |
| Example | 350 | A | 2.0 | 70 | C | 0.60 | B | 0.30 | B | 200 | 200 | 1605 | 110 | B |
| 8 | | | | | | | | | | | | | | |
| Example | 350 | A | 2.0 | 80 | C | 0.20 | A | 0.20 | B | 200 | 200 | 1655 | 120 | B |
| 9 | | | | | | | | | | | | | | |
| Example | 350 | A | 2.0 | 60 | B | 0.34 | B | 0.21 | B | 200 | 200 | 755 | 70 | B |
| 10 | | | | | | | | | | | | | | |
| Example | 350 | A | 2.0 | 55 | B | 0.20 | A | 0.21 | B | 200 | 200 | 655 | 50 | A |
| 11 | | | | | | | | | | | | | | |
| Example | 350 | A | 2.0 | 50 | A | 0.15 | A | 0.13 | A | 200 | 200 | 655 | 50 | A |
| 12 | | | | | | | | | | | | | | |
| Example | 360 | A | 2.0 | 55 | B | 0.15 | A | 0.13 | A | 200 | 200 | 655 | 50 | A |
| 13 | | | | | | | | | | | | | | |
| Example | 360 | A | 2.0 | 60 | B | 0.15 | A | 0.12 | A | 200 | 200 | 655 | 50 | A |
| 14 | | | | | | | | | | | | | | |
| Example | 360 | | 4.0 | 65 | C | 0.15 | A | 0.12 | A | 200 | 200 | 655 | 50 | A |
| 15 | | | | | | | | | | | | | | |
| Example | 320 | B | 2.0 | 50 | A | 1.50 | C | 0.45 | B | 200 | 200 | 1005 | 120 | B |
| 16 | | | | | | | | | | | | | | |
| Example | 320 | | 4.0 | 60 | B | 1.50 | C | 0.45 | B | 200 | 200 | 1005 | 120 | B |
| 17 | | | | | | | | | | | | | | |
| Example | 320 | B | 2.0 | 55 | B | 1.00 | C | 0.37 | B | 200 | 200 | 1305 | 130 | B |
| 18 | | | | | | | | | | | | | | |
| Example | 290 | C | 2.0 | 80 | C | 0.20 | A | 0.24 | B | 200 | 200 | 1494 | 110 | B |
| 19 | | | | | | | | | | | | | | |
| Example | 300 | B | 2.0 | 80 | C | 0.20 | A | 0.17 | A | 200 | 200 | 1484 | 110 | B |
| 20 | | | | | | | | | | | | | | |
| Example | 290 | C | 2.0 | 70 | C | 0.20 | A | 0.30 | B | 200 | 200 | 655 | 100 | B |
| 21 | | | | | | | | | | | | | | |

TABLE 4

| | photo- | photo- | photo- | | | | | | | | |
|---|---|---|---|---|---|---|---|---|---|---|---|
| | sensitive | sensitive | sensitive | (1) evaluation for ion elution quantity and conductivity of organic insulating film (P1) | | | | | | | |
| | varnish | varnish | sheet | | | | | | | | |
| | used for | used for | used for | | | (in- | (in- | (in- | | | |
| | organic | hollow | hollow | | | cluding) | cluding) | cluding) | (in- | | |
| | insulating | structure | structure | ion elution | | acetate | formate | propionate | cluding) | conduc- | |
| | film | support | roof member | quantity | | ion | ion | ion | sulfate ion | tivity | |
| | (P1) | member (P2) | (P3) | (ppm) | | (ppm) | (ppm) | (ppm) | (ppm) | (μS/cm) | |
| Example 22 | P1-10 | P2-1 | P3-1 | 215 | A | 130 | 80 | 5 | 0 | 290 | A |
| Example 23 | P1-10 | P2-1 | P3-1 | 175 | A | 110 | 60 | 5 | 0 | 250 | A |
| Example 24 | P1-6 | P2-1 | P3-1 | 655 | B | 50 | 600 | 5 | 0 | 370 | B |
| Comparative | P1-22 | P2-1 | P3-1 | 3005 | C | 2100 | 900 | 5 | 0 | 560 | C |
| example 1 | | | | | | | | | | | |
| Comparative | P1-23 | P2-1 | P3-1 | 2805 | C | 1900 | 900 | 5 | 0 | 550 | C |
| example 2 | | | | | | | | | | | |
| Comparative | P1-24 | P2-1 | P3-1 | 2705 | C | 1800 | 900 | 5 | 0 | 530 | C |
| example 3 | | | | | | | | | | | |
| Comparative | P1-25 | P2-1 | P3-1 | 2105 | C | 1800 | 300 | 5 | 0 | 520 | C |
| example 4 | | | | | | | | | | | |
| Comparative | P1-26 | P2-1 | P3-1 | 2605 | C | 50 | 350 | 5 | 2200 | 550 | C |
| example 5 | | | | | | | | | | | |
| Comparative | P1-27 | P2-1 | P3-1 | 555 | B | 50 | 350 | 5 | 150 | 400 | B |
| example 6 | | | | | | | | | | | |
| Comparative | P1-28 | P2-1 | P3-1 | 125 | A | 20 | 100 | 5 | 0 | 250 | A |
| example 7 | | | | | | | | | | | |
| Comparative | P1-29 | P2-1 | P3-1 | 2105 | C | 1800 | 300 | 5 | 0 | 600 | C |
| example 8 | | | | | | | | | | | |

| | (2) | | | | | | | | | | | | | |
|---|---|---|---|---|---|---|---|---|---|---|---|---|---|---|
| | evaluation | | | | | | | | | | | | | |
| | for heat | | | | | | | | | (3) evaluation of hollow structure | | | | |
| | resistance | | | | | | | | | | | total ion | corrosion | |
| | of organic | | (2) evaluation of laminate | | | | | | | | | elution | resistant | |
| | insulating | | | | | development | | | | ion | ion | quantity | copper | |
| | film (P1) | | | taper | | film loss | | chemical | | elution | elution | of (P1) | oxide | |
| | weight loss | | thickness | angle of | | variation of | | resistance | | quantity | quantity | (P2) | layer | |
| | temperature | | of (P1) | (P1) | | (P1) | | of (P1) | | of (P2) | of (P3) | (P3) | thickness | |
| | (° C.) | | (μm) | (°) | | (μm) | | (μm) | | (ppm) | (ppm) | (ppm) | (μm) | |
| Example 22 | 350 | A | 2.0 | 20 | A | 0.15 | A | 0.13 | A | 200 | 200 | 615 | 50 | A |
| Example 23 | 350 | A | 2.0 | 15 | C | 0.15 | A | 0.13 | A | 200 | 200 | 575 | 40 | A |
| Example 24 | 350 | A | 2.0 | 70 | C | 0.23 | B | 0.12 | A | 200 | 200 | 1055 | 80 | B |
| Comparative | 350 | A | 2.0 | 80 | C | 0.16 | A | 0.2 | A | 200 | 200 | 3405 | 150 | C |
| example 1 | | | | | | | | | | | | | | |
| Comparative | 350 | A | 2.0 | 80 | C | 0.18 | A | 0.2 | A | 200 | 200 | 3205 | 150 | C |
| example 2 | | | | | | | | | | | | | | |
| Comparative | 350 | A | 2.0 | 70 | C | 0.20 | A | 0.2 | A | 200 | 200 | 3105 | 150 | C |
| example 3 | | | | | | | | | | | | | | |
| Comparative | 350 | A | 2.0 | 60 | B | 0.20 | A | 0.23 | B | 200 | 200 | 2505 | 150 | C |
| example 4 | | | | | | | | | | | | | | |
| Comparative | 300 | B | 2.0 | 55 | B | 0.20 | A | 0.3 | B | 200 | 200 | 3005 | 160 | C |
| example 5 | | | | | | | | | | | | | | |
| Comparative | 350 | A | 2.0 | — | — | — | — | — | — | — | — | — | — | — |
| example 6 | | | | | | | | | | | | | | |
| Comparative | 290 | C | 2.0 | — | — | — | — | — | — | — | — | — | — | — |
| example 7 | | | | | | | | | | | | | | |
| Comparative | 350 | A | 2.0 | 65 | C | 0.10 | A | 0.2 | A | 200 | 200 | 2505 | 170 | C |
| example 8 | | | | | | | | | | | | | | |

### EXPLANATION OF NUMERALS

1 piezoelectric substrate
2 metal wire (M1)
3 organic insulating film (P1)
4 metal wire (M2)
5 hollow structure support member (P2)
6 hollow structure roof member (P3)
7 the part illustrated in in FIG. 2
c the angle formed between the plane where the piezoelectric substrate is in contact with the metal wire (M1) and the plane where the relief pattern of the organic insulating film (P1) is in contact with the metal wire (M2)

1. A laminate comprising:
a metal wire (M1) with a thickness of 0.1 to 5 μm,
a relief pattern of an organic insulating film (P1) with a thickness of 0.5 to 4 μm, and
a metal wire (M2) with a thickness of 0.1 to 5 μm
which are disposed in this order on a piezoelectric substrate,
wherein the organic insulating film (P1) includes a cured product obtainable by curing a photosensitive resin composition containing an alkali soluble resin (A), an oxime based photopolymerization initiator (B), and a radical polymerizable compound (C),
the oxime based photopolymerization initiator (B) accounting for 1 to 20 parts by mass relative to 100 parts by mass of the alkali soluble resin (A),
the oxime based photopolymerization initiator (B) containing a compound as represented by the formula (1) and a compound as represented by the formula (2),
the ratio in mass between the compound represented by the formula (1) and the compound represented by the formula (2) being 1:1 to 20:1, and
the ion elution quantity from the organic insulating film (P1) being 2,000 ppm or less as determined by the ion elution quantity measurement method described below:
(ion elution quantity measurement method)
the organic film is immersed in pure water with a mass ten times that of the film and then subjected to hot water extraction at 121° C. for 20 hours, followed by collecting the supernatant of the extract to provide a test liquid, and the test liquid and standard solutions of the target ions are introduced into an ion chromatograph, and the concentrations of the formate ion, acetate ion, propionate ion, and sulfate ion in the test liquid are measured by the working curve based measurement method and converted to the mass of eluted ions relative to the mass of the organic film to determine the ion elution quantity: 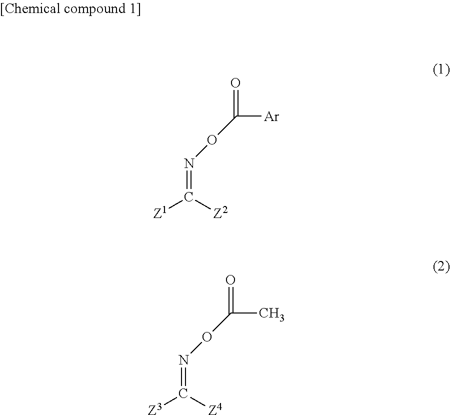
wherein in the formula (1), Ar is an aryl group having 6 to 20 carbon atoms, Z¹ an organic group as represented by any of formulas (3) to (6), and Z² a hydrogen atom or a monovalent organic group having 1 to 20 carbon atoms, and in the formula (2), Z³ is an organic group as represented by any of the formulas (3) to (6), and Z⁴ is a hydrogen atom or a monovalent organic group having 1 to 20 carbon atoms, 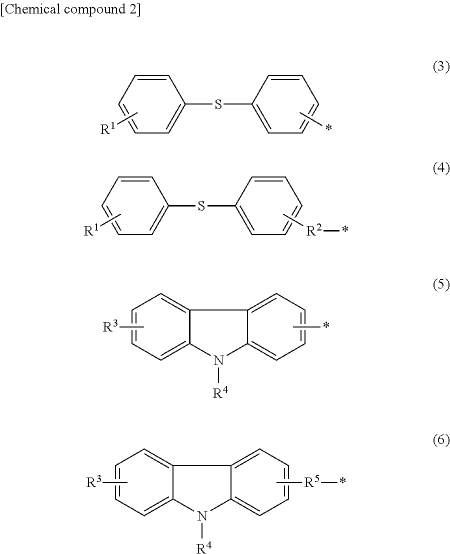
wherein in the formulas (3) to (6), R¹ and R³ each denote a hydrogen atom or a monovalent organic group having 1 to 20 carbon atoms: R² and R⁵ each denote a divalent organic group having 1 to 20 carbon atoms; and R⁴ denotes a monovalent organic group having 1 to 20 carbon atoms.

2. A laminate comprising:
a metal wire (M1) with a thickness of 0.1 to 5 μm,
a relief pattern of an organic insulating film (P1) with a thickness of 0.5 to 4 μm, and
a metal wire (M2) with a thickness of 0.1 to 5 μm
which are disposed in this order on a piezoelectric substrate,
wherein the organic insulating film (P1) includes a cured product obtainable by curing a photosensitive resin composition containing an alkali soluble resin (A) and a naphthoquinone diazide compound (E),
the naphthoquinone diazide compound (E) accounting for 5 to 25 parts by mass relative to 100 parts by mass of the alkali soluble resin (A), and
the ion elution quantity from the organic insulating film (P1) being 2,000 ppm or less as determined by the ion elution quantity measurement method described below:
(ion elution quantity measurement method)
the organic film is immersed in pure water with a mass ten times that of the film and then subjected to hot water extraction at 121° C. for 20 hours, followed by collecting the supernatant of the extract to provide a test liquid, and the test liquid and standard solutions of the target ions are introduced into an ion chromatograph, and the concentrations of the formate ion, acetate ion, propionate ion, and sulfate ion in the test liquid are measured by the working curve based measurement method and converted to the mass of eluted ions relative to the mass of the organic film to determine the ion elution quantity.

3. The laminate according to claim 1, wherein the test liquid of the organic insulating film (P1) prepared above in the procedure for ion elution quantity measurement method has a conductivity of 500 μS/cm or less.

4. The laminate according to claim 1, wherein the plane where the piezoelectric substrate is in contact with the metal wire (M1) makes an angle of 20° to 60° with the plane where the relief pattern of the organic insulating film (P1) is in contact with the metal wire (M2).

5. The laminate according to claim 1, wherein the alkali soluble resin (A) comprises at least one selected from the group consisting of polyimide, polybenzoxazole, polyamide, precursors thereof, and copolymers thereof.

6. The laminate according to claim 2, wherein the ratio in mass between the compound represented by the formula (1) and the compound represented by the formula (2) is 4:1 to 20:1.

7. The laminate according to claim 2, wherein the radical polymerizable compound (C) further comprises a compound as represented by the formula (7) and a compound as represented by the formula (8), the ratio in mass between the compound represented by the formula (7) and the compound represented by the formula (8) being 1:9 to 5:5: 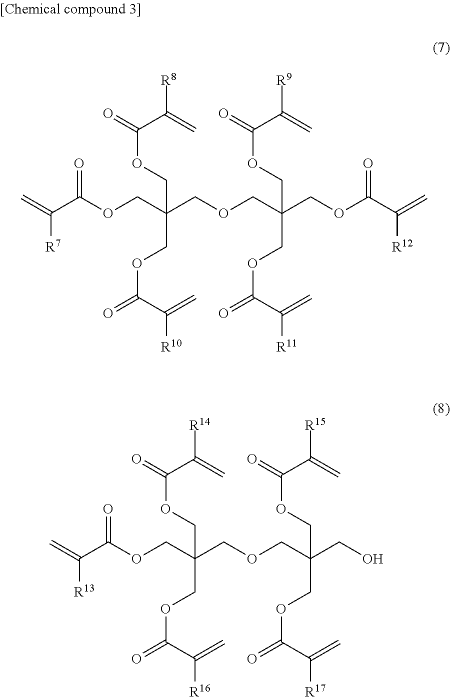
wherein in the formulas (7) and (8), R⁷ to R¹⁷ are each independently a hydrogen atom or a methyl group.

8. The laminate according to claim 1, wherein the photosensitive resin composition comprises a thermally crosslinkable compound (D), the thermally crosslinkable compound (D) comprising a polyfunctional epoxy group-containing compound (D-1) and a polyfunctional alkoxymethyl group-containing compound (D-2), the polyfunctional epoxy group-containing compound (D-1) accounting for 5 to 30 parts by mass relative to 100 parts by mass of the alkali soluble resin (A), and the polyfunctional alkoxymethyl group-containing compound (D-2) accounting for 1 to 10 parts by mass relative thereto.

9. A method for manufacturing a laminate comprising the following steps in that order:
a step (1) for forming a metal wire (M1) on a piezoelectric substrate,
a step (2) for applying a photosensitive resin composition over the piezoelectric substrate and the metal wire (M1) and drying it by heating at 80° C. to 130° C. to form a photosensitive resin film on the substrate,
a step (3) for exposing the photosensitive resin film to light through a mask to an exposure dose of 150 to 2,000 mJ/cm²,
a step (4) for heating the light-exposed photosensitive resin film at 80° C. to 130° C.,
a step (5) for removing the unexposed region with an alkaline aqueous solution to develop the photosensitive resin film,
a step (6) for heat-treating the developed photosensitive resin film at 200° C. to 280 to form a relief pattern of an organic insulating film (P1), and
a step (7) for forming a metal wire (M2) on the piezoelectric substrate and the organic insulating film (P1).

10. The method for manufacturing a laminate according to claim 9, wherein the thickness of the light-exposed region of the photosensitive resin film after developing for 80 seconds and that after developing for 140 seconds in the step (5) differ by 0.20 μm or less.

11. The method for manufacturing a laminate according to claim 9, further comprising a step (5-1) between the step (5) and the step (6) for heating the developed photosensitive resin film from a temperature of 100° C. or less to a temperature of 150° C. to 200° C. at a heating rate of 10° C./min or more.

12. The method for manufacturing a laminate according to claim 9, further comprising a step (5-2) between the step (5) and the step (6) for exposing the developed photosensitive resin film to light to an exposure dose of 1,000 to 3,000 mJ/cm².

13. A hollow structure comprising the laminate according to claim 1, a hollow structure support member (P2), and a hollow structure roof member (P3).

14. The hollow structure according to claim 13, wherein the hollow structure support member (P2) and the hollow structure roof member (P3) are organic films each containing at least one alkali soluble resin (A) selected from the group consisting of polyimide, polybenzoxazole, polyamide, precursors thereof, and copolymers thereof.

15. The hollow structure according to claim 13, wherein the total ion elution quantity of the organic insulating film (P1) with a thickness of 0.5 to 4 μm, the hollow structure support member (P2), and the hollow structure roof member (P3) is 2,000 ppm or less, wherein the organic insulating film (P1) with a thickness of 0.5 to 4 μm, the hollow structure support member (P2), and the hollow structure roof member (P3) are examined separately by the ion elution quantity measurement method.

16. An electronic component comprising the hollow structure according to claim 13.
